(19) United States
(12) Patent Application Publication
(10) Pub. No.: US 2024/0179913 A1
(43) Pub. Date: May 30, 2024

(54) SEMICONDUCTOR DEVICE AND DATA STORAGE SYSTEM INCLUDING SEMICONDUCTOR DEVICE

(71) Applicant: Samsung Electronics Co., Ltd., Suwon-si (KR)

(72) Inventors: Hyunmook CHOI, Suwon-si (KR); Jihong KIM, Suwon-si (KR); Hyunmog PARK, Suwon-si (KR)

(73) Assignee: Samsung Electronics Co., Ltd., Suwon-si (KR)

(21) Appl. No.: 18/489,224

(22) Filed: Oct. 18, 2023

(30) Foreign Application Priority Data
Nov. 24, 2022 (KR) 10-2022-0159622

(51) Int. Cl. H10B 43/27; H01L 25/065; H10B 41/10; H10B 41/27; H10B 41/35; H10B 43/10; H10B 43/35; H10B 80/00

(52) U.S. Cl. CPC H10B 43/27; H01L 25/0652; H10B 41/10; H10B 41/27; H10B 41/35; H10B 43/10; H10B 43/35; H10B 80/00; H01L 2225/06506; H01L 2225/0651

(57) ABSTRACT

A semiconductor device including first gate electrodes stacked on a substrate and spaced apart from each other, a first channel structure passing through the first gate electrodes, the first channel structure including a first channel layer, a first dielectric layer between the first channel layer and the first gate electrodes, a first buried insulating layer filling an interior of the first channel layer, an auxiliary channel layer covering at least a portion of the first channel layer and the first dielectric layer, and a first channel pad on the first buried insulating layer, and isolation regions passing through the first gate electrodes, the isolation regions and spaced apart from each other may be provided. The auxiliary channel layer may be in contact with the first channel pad. The first channel pad may be spaced apart from the first dielectric layer by the auxiliary channel layer.

### CROSS-REFERENCE TO RELATED APPLICATION(S)

This application claims benefit of priority to Korean Patent Application No. 10-2022-0159622, filed on Nov. 24, 2022, with the Korean Intellectual Property Office, the disclosure of which is incorporated herein by reference in its entirety.

### BACKGROUND

The present disclosure relates to semiconductor devices and/or data storage systems including the same.

In a data storage system requiring data storage, a semiconductor device capable of storing high-capacity data is in demand. Accordingly, a method of increasing a data storage capacity of a semiconductor device is being researched. For example, for increasing data storage capacity of a semiconductor device, a semiconductor device including memory cells arranged three-dimensionally, instead of memory cells arranged two-dimensionally, has been proposed.

### SUMMARY

An aspect of the present disclosure provides a semiconductor device having an improved degree of integration and improved reliability.

Another aspect of the present disclosure provides a data storage system including a semiconductor device having an improved degree of integration and improved reliability.

According to an aspect of the present disclosure, a semiconductor device includes first gate electrodes stacked on a substrate and spaced apart from each other, a first channel structure passing through the first gate electrodes, the first channel structure including a first channel layer, a first dielectric layer between the first channel layer and the first gate electrodes, a first buried insulating layer filling an interior of the first channel layer, an auxiliary channel layer covering at least a portion of the first channel layer and the first dielectric layer, and a first channel pad on the first buried insulating layer, and isolation regions passing through the first gate electrodes and spaced apart from each other. The auxiliary channel layer may be in contact with the first channel pad. The first channel pad may be spaced apart from the first dielectric layer by the auxiliary channel layer.

According to another aspect of the present disclosure, a semiconductor device includes first gate electrodes stacked on a substrate and spaced apart from each other, a first channel structure passing through the first gate electrodes, the first channel structure including a first channel layer, a first dielectric layer between the first channel layer and the first gate electrodes, a first buried insulating layer filling an interior of the first channel layer, an auxiliary channel layer covering at least a portion of the first channel layer and the first dielectric layer, and a first channel pad on the first buried insulating layer, and isolation regions passing through the first gate electrodes and spaced apart from each other. The auxiliary channel layer may be in contact with the first channel pad. A lower surface of the first channel pad may be positioned on a level higher than an upper surface of the first channel layer.

According to another aspect of the present disclosure, a data storage system includes a semiconductor storage device including through a lower substrate, circuit elements on one side of the lower substrate, an upper substrate on the circuit elements, first gate electrodes stacked on the upper substrate and spaced apart from each other, a first channel structure passing through the first gate electrodes, and isolation regions passing through the first gate electrodes and spaced apart from each other, and an input/output pad electrically connected to the circuit elements, and a controller electrically connected to the semiconductor storage device through the input/output pad, the controller controlling the semiconductor storage device. The first channel structure may include a first channel layer, a first dielectric layer between the first channel layer and the first gate electrodes, a first buried insulating layer filling an interior of the first channel layer, an auxiliary channel layer covering at least a portion of the first channel layer and the first dielectric layer, and a first channel pad on the first buried insulating layer. The auxiliary channel layer may be in contact with the first channel pad. A lower surface of the first channel pad may be at on a level higher than an upper surface of the first channel layer.

### BRIEF DESCRIPTION OF DRAWINGS

The above and other aspects, features, and advantages of example embodiments of the present inventive concepts will be more apparent understood from the following detailed description, taken in conjunction with the accompanying drawings, in which:

FIG. 1 is a schematic plan view of a semiconductor device according to an example embodiment;

FIG. 2A is a schematic cross-sectional view of a semiconductor device according to an example embodiment;

FIGS. 2B, 2C, 2D and 2E are partially enlarged views of a semiconductor device according to some example embodiments;

FIGS. 3, 4A, 4B, 4C, 4D, 5A, 5B, 5C, 6A, 6B, 6C, 7 and 8 are partially enlarged schematic views of semiconductor devices according to some example embodiments;

FIGS. 9, 10 and 11 are schematic cross-sectional views of a semiconductor device according to some example embodiments;

FIGS. 12A, 12B, 12C, 12D, 12E, 12F, 12G, 12H and 12I are schematic cross-sectional views and partially enlarged views illustrating a method of manufacturing a semiconductor device according to an example embodiment;

FIG. 13 is a schematic diagram illustrating a data storage system including a semiconductor device according to an example embodiment;

FIG. 14 is a schematic perspective view of a data storage system including a semiconductor device according to an example embodiment; and

FIG. 15 is a schematic cross-sectional view of a semiconductor package according to an example embodiment.

### DETAILED DESCRIPTION

Hereinafter, some example embodiments of the present disclosure will be described below with reference to the accompanying drawings.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., +10%).

When the terms “about” or “substantially” are used in this specification in connection with a numerical value, it is intended that the associated numerical value includes a manufacturing or operational tolerance (e.g., +10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes.

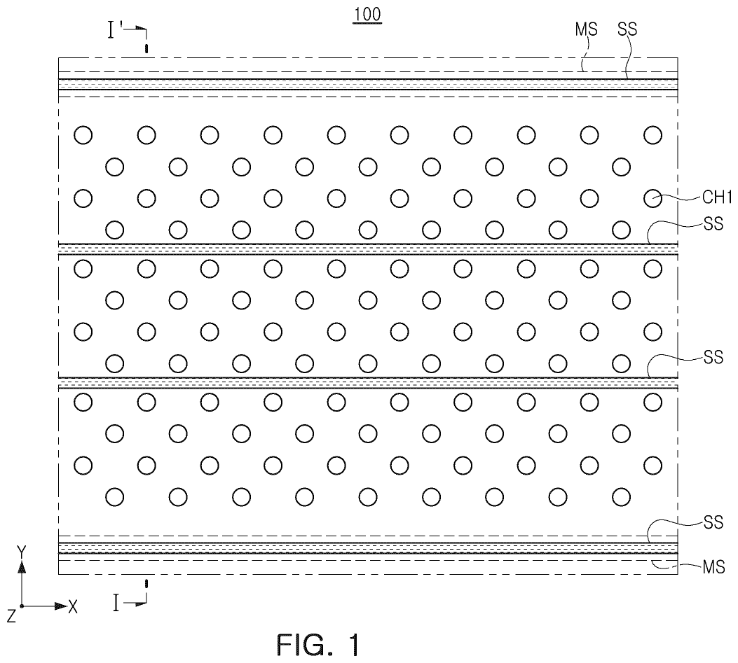

FIG. 1 is a schematic plan view of a semiconductor device according to an example embodiment.

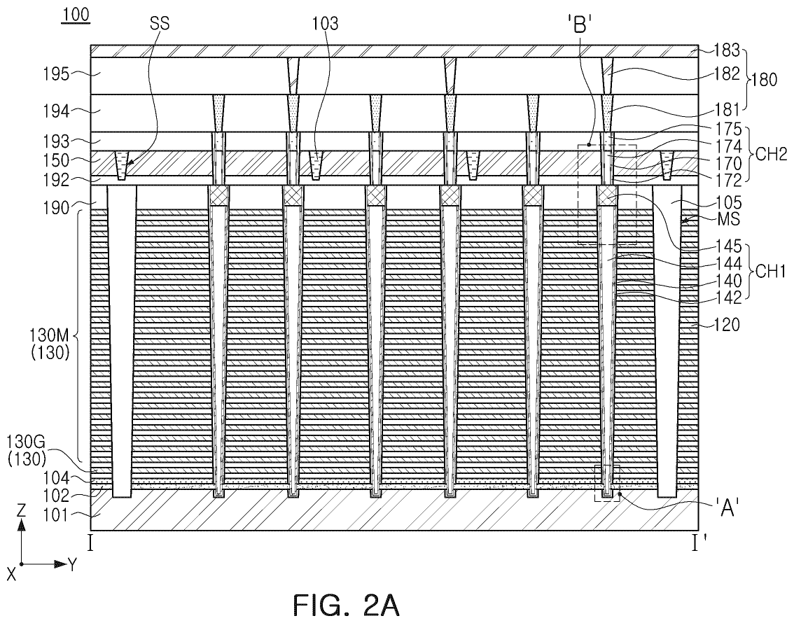

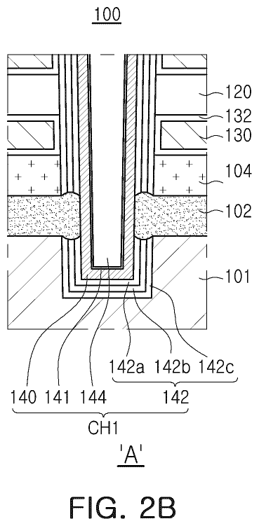

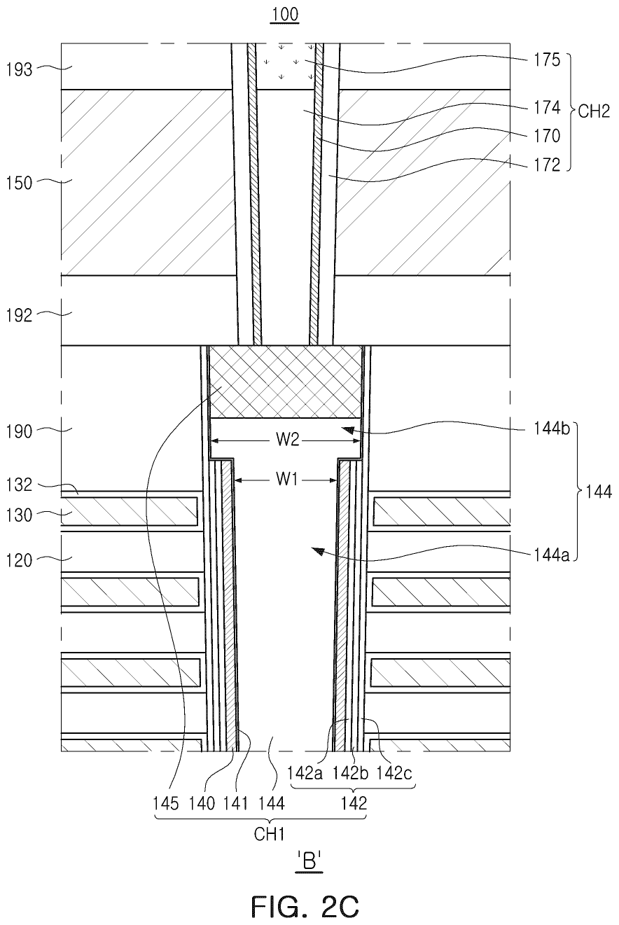

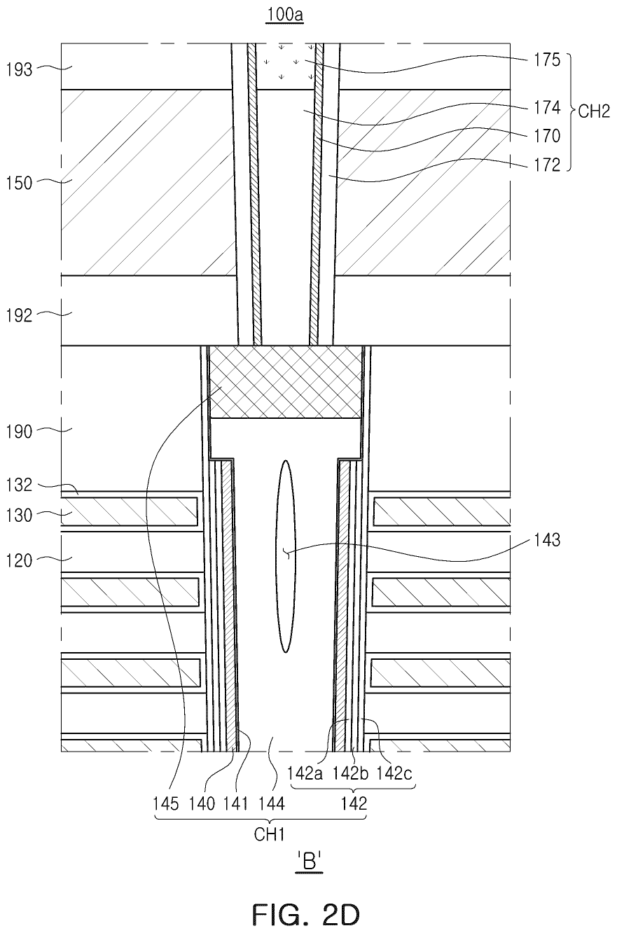

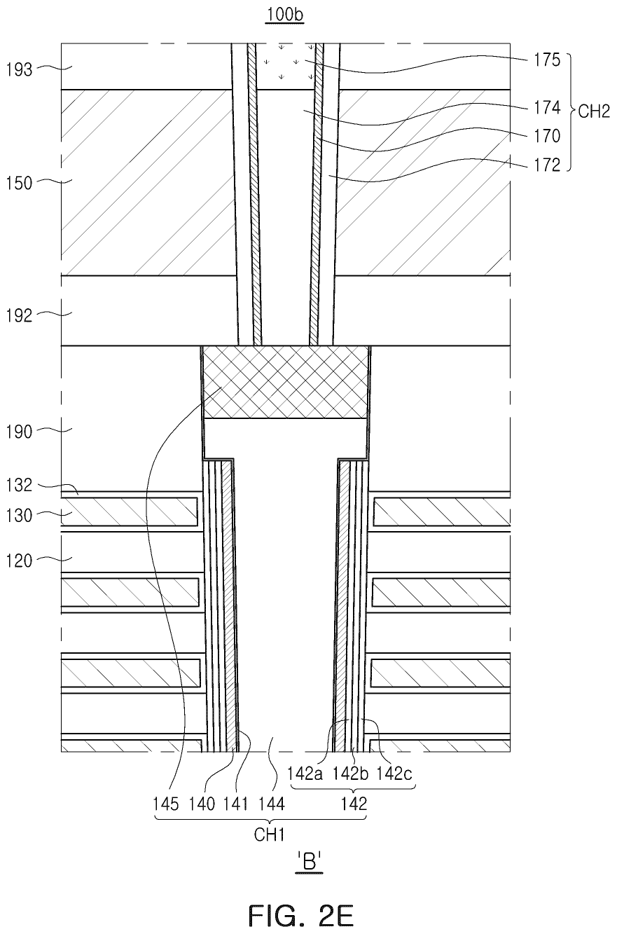

FIG. 2A is a schematic cross-sectional view of a semiconductor device according to an example embodiment. FIG. 2A illustrates a cross-section taken along line I-I′ of FIG. 1.

FIG. 2B is a partially enlarged view of a semiconductor device according to example embodiments. FIG. 2B is an enlarged view of region “A” of FIG. 2A.

FIG. 2C is a partially enlarged view of a semiconductor device according to example embodiments. FIG. 2C is an enlarged view of region “B” of FIG. 2A.

Referring to FIGS. 1 to 2C, a semiconductor device 100 may include a substrate 101, first and second horizontal conductive layers 102 and 104 on the substrate 101, first gate electrodes 130 stacked on the substrate 101, interlayer insulating layers 120 stacked on the substrate 101 alternately with the first gate electrodes 130, first channel structures CH1 respectively including a first channel layer 140 and an auxiliary channel layer 141, first channel structures CH1 disposed to pass through a stack structure including the gate electrodes 130 and the interlayer insulating layers 120, and isolation regions MS extending through the stack structure. The semiconductor device 100 may further include a first upper insulating layer 192 on the first channel structures CH1 and the isolation regions MS, a second gate electrode 150 on the first upper insulating layer 192, and second channel structures CH2 disposed to pass through the second gate electrode 150, the second channel structures CH2 each including a second channel layer 170, upper isolation regions SS extending through the second gate electrode 150, a cell region insulating layer 190 covering the stack structure below the first upper insulating layer 192, upper insulating layers 192, 193, 194, and 195 on the cell region insulating layer 190, and an upper interconnection structure 180 connected to each of the second channel structures CH2.

As illustrated in FIG. 1, in the semiconductor device 100, one memory cell string may be configured based on each channel structure CH, and a plurality of memory cell strings may be arranged in columns and rows in an X-direction and a Y-direction.

The substrate 101 may have an upper surface extending in the X-direction and the Y-direction. The substrate 101 may include a semiconductor material, for example, a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, an epitaxial layer, a silicon on insulator (SOI) layer, or a semiconductor on insulator (SeOI) layer.

The first and second horizontal conductive layers 102 and 104 may be disposed to be stacked on an upper surface of the substrate 101. The first horizontal conductive layer 102 may function as at least a portion of a common source line of the semiconductor device 100, and may function as a common source line together with the substrate 101. As illustrated in the enlarged view of FIG. 2B, the first horizontal conductive layer 102 may be directly connected to the first channel layer 140 around the first channel layer 140.

The first and second horizontal conductive layers 102 and 104 may include a semiconductor material, for example, polycrystalline silicon. In this case, at least the first horizontal conductive layer 102 may be a layer doped with impurities having a conductivity type the same as that of the substrate 101, and the second horizontal conductive layer 104 may be a doped layer or may be a layer including impurities diffused from the first horizontal conductive layer 102. However, a material of the second horizontal conductive layer 104 is not limited to a semiconductor material, and may be replaced with an insulating layer in some example embodiments.

The first gate electrodes 130 may be vertically spaced apart from each other and stacked on the substrate 101 to form a stack structure. The first gate electrodes 130 may include a lower gate electrode 130G forming a gate of a ground selection transistor and memory gate electrodes 130M forming a plurality of memory cells. The number of memory gate electrodes 130M forming memory cells may be determined depending on a capacity of the semiconductor device 100. In some example embodiments, one or more lower gate electrodes 130G may be formed, and may have the same structure as or a different structure from the memory gate electrodes 130M. In some example embodiments, the first gate electrodes 130 may further include a gate electrode 130 disposed below the lower gate electrode 130G and forming an erase transistor used for an erase operation using a gate induced drain leakage (GIDL) phenomenon. In addition, a portion of the first gate electrodes 130, for example, memory gate electrodes 130M adjacent to the lower gate electrode 130G may be dummy gate electrodes.

The first gate electrodes 130 may include a metal material, for example, tungsten (W). In some example embodiment, the first gate electrodes 130 may include polycrystalline silicon or a metal silicide material. In some example embodiments, the first gate electrodes 130 may further include a diffusion barrier. For example, the diffusion barrier may include tungsten nitride (WN), tantalum nitride (TaN), titanium nitride (TiN), or combinations thereof.

The interlayer insulating layers 120 may be disposed between the first gate electrodes 130. In the same manner as the first gate electrodes 130, the interlayer insulating layers 120 may also be disposed to be spaced apart from each other in a direction, perpendicular to the upper surface of the substrate 101. The interlayer insulating layers 120 may include an insulating material such as silicon oxide or silicon nitride.

The first channel structures CH1 may respectively form one memory cell string, and may be disposed on the substrate 101 in rows and columns to be spaced apart from each other. The first channel structures CH1 may form a lattice pattern or to have a zigzag shape in one direction, on an X-Y plane. In an example, the first channel structures CH1 may be disposed to have a zigzag pattern by six channel structures arranged in a first column and six channel structures arranged in a second column between adjacent isolation regions MS. However, the arrangement of the first channel structures CH1 is not limited thereto and may be changed in various manners. The first channel structures CH1 may have a columnar shape, and may have inclined side surfaces such that a horizontal width of the first channel structures CH1 becomes narrower as a distance to the substrate 101 decreases depending on aspect ratio. As illustrated in the enlarged view of FIG. 2C, each of the first channel structures CH1 may further include, in addition to the first channel layer 140, a first dielectric layer 142, an auxiliary channel layer 141 on the first channel layer 140, a first buried insulating layer 144 between the auxiliary channel layers 141, and a first channel pad 145 on the first buried insulating layer 144.

The first channel layer 140 may be formed to have an annular shape surrounding the auxiliary channel layer 141 and the first buried insulating layer 144 therein. However, in some example embodiments, the first channel layer 140 may have a columnar shape such as a cylinder or a prism, without the first buried insulating layer 144. A lower portion of the first channel layer 140 may be connected to the first horizontal conductive layer 102. The first channel layer 140 may include a semiconductor material such as polycrystalline silicon or single crystal silicon, and the semiconductor material may be an undoped material or a material including P-type or N-type impurities.

The first dielectric layer 142 may be disposed between the first gate electrodes 130 and the first channel layer 140. Referring to FIGS. 2B and 2C, the first dielectric layer 142 may include a tunneling layer 142a, a charge storage layer 142b, and a blocking layer 142c sequentially stacked from the first channel layer 140. The tunneling layer 142a may tunnel charges into the charge storage layer 142b, and may include, for example, silicon oxide (SiO₂), silicon nitride (Si₃N₄), silicon oxynitride (SiON), or combinations thereof. The charge storage layer 142b may be a charge trap layer or a floating gate conductive layer. The blocking layer 142c may include silicon oxide (SiO₂), silicon nitride (Si₃N₄), silicon oxynitride (SiON), a high-k dielectric material, or combinations thereof. According to an example embodiment, an upper surface of the first dielectric layer 142 may be disposed on a level the same as or substantially similar to that of an upper surface of the first channel layer 140. For example, upper surfaces of the tunneling layer 142a and the charge storage layer 142b may be disposed on a level the same as or substantially similar to the upper surface of the first channel layer 140, but example embodiments of the present disclosure are not limited thereto. According to some example embodiments, the semiconductor device 100 may include a gate dielectric layer 132 disposed between the first gate electrodes 130 and the interlayer insulating layers 120 and between the first gate electrodes 130 and the first channel structures CH1. The gate dielectric layer 132 may serve to block or prevent charges in the charge storage layer 142b from moving to the first gate electrodes 130, together with the blocking layer 142c.

The auxiliary channel layer 141 may cover at least a portion of the first channel layer 140 and the first dielectric layer 142. The auxiliary channel layer 141 may be in contact with the first channel pad 145. For example, the auxiliary channel layer 141 may be in contact with a side surface of the first channel pad 145. According to an example embodiment, the auxiliary channel layer 141 may conformally cover the upper surface of the first dielectric layer 142 and the upper surface of the first channel layer 140, but example embodiments of the present disclosure are not limited thereto. The auxiliary channel layer 141 may be disposed along an external side surface of the first buried insulating layer 144, an external side surface of the first channel pad 145, and an internal side surface of the first channel layer 140. The auxiliary channel layer 141 may include a semiconductor material such as polycrystalline silicon or single crystal silicon, and the semiconductor material may be an undoped material or a material including P-type or N-type impurities. The auxiliary channel layer 141 may include the same material as the first channel layer 140, but is not limited thereto. According to an example embodiment, a thickness of the auxiliary channel layer 141 may be different from that of the first channel layer 140. For example, the thickness of the auxiliary channel layer 141 may be less than the thickness of the first channel layer 140, but example embodiments of the present disclosure are not limited thereto.

The first buried insulating layer 144 may be disposed on the inside of the auxiliary channel layer 141. The first buried insulating layer 144 may be disposed below the first channel pad 145. The first buried insulating layer 144 may have a shape having a width decreasing toward the substrate 101 due to a high aspect ratio. The first buried insulating layer 144 may include at least one of silicon oxide, silicon nitride, and silicon oxynitride. According to an example embodiment, the first buried insulating layer 144 may include a first region 144a positioned on a level the same as that of the first channel layer 140, and a second region 144b positioned on a level higher than that of the first channel layer 140. A first width W1 of the first region 144a may be less than a second width W2 of the second region 144b.

The first channel pad 145 may be disposed to cover an upper surface of the first buried insulating layer 144 and to be electrically connected to the first channel layer 140 through the auxiliary channel layer 141. The first channel pad 145 may be spaced apart from the first channel layer 140 and may be disposed on an upper portion of the first channel layer 140. The first channel pad 145 may include, for example, polycrystalline silicon. The first channel pad 145 may be spaced apart from the first dielectric layer 142 by the auxiliary channel layer 141. According to an example embodiment, a lower surface of the first channel pad 145 may be positioned on a level higher than that of the upper surface of the first channel layer 140. The first channel pad 145 may overlap the first channel layer 140 in a Z-direction. The first channel pad 145 may be spaced apart from the first channel layer 140 in the Z-direction. A width of the first channel pad 145 may be wider than a width between external side surfaces of the first channel layer 140. Thus, a contact area with the second channel structures CH2 to be described below may be secured, and a misalignment margin between the first channel pad 145 and the second channel structures CH2 may be secured, thereby providing the semiconductor device 100 having an improved degree of integration and improved reliability. According to an example embodiment, the first channel pad 145 may be electrically connected to the auxiliary channel layer 141 and the first channel layer 140. A distance between an upper surface of the first channel pad 145 and an upper surface of the tunneling layer 142a, a distance between the upper surface of the first channel pad 145 and an upper surface of the charge storage layer 142b, and a distance between the upper surface of the first channel pad 145 and the first channel layer 140 may be the same or substantially similar.

The isolation regions MS may pass through the first gate electrodes 130, the interlayer insulating layers 120, and the first and second horizontal conductive layers 102 and 104 to extend in the Z-direction, to extend in the X-direction, and to be connected to the substrate 101. As illustrated in FIG. 1, the isolation regions MS may be disposed to be spaced apart from each other and to be in parallel in the Y-direction. The isolation regions MS may be in the form of a trench extending in the X-direction. The isolation regions MS may isolate the first gate electrodes 130 from each other in the Y-direction. The isolation regions MS may have a shape having a width decreasing toward the substrate 101 due to a high aspect ratio. An isolation insulating layer 105 may be disposed in the isolation regions MS. The isolation insulating layer 105 may include at least one of silicon oxide, silicon nitride, and silicon oxynitride. However, in some example embodiments, a conductive material layer may be disposed in the isolation regions MS.

The cell region insulating layer 190 may cover the stack structure including the first gate electrodes 130 and the interlayer insulating layers 120. The cell region insulating layer 190 may cover at least a portion of side surfaces of the isolation regions MS and/or the first channel structures CH1, for example, a portion extending upwardly from the stack structure. In an example embodiment, an upper surface of the cell region insulating layer 190 may be positioned on a level the same as or substantially similar to that of an upper surface of each of the first channel structures CH1. The upper surface of the cell region insulating layer 190 may be positioned on a level the same as or substantially similar to that of the upper surface of each of the isolation regions MS, but example embodiments of the present disclosure are not limited thereto. The cell region insulating layer 190 may include at least one of silicon oxide, silicon nitride, and silicon oxynitride.

The first upper insulating layer 192 may be disposed on the first channel structures CH1 and the isolation regions MS. The first upper insulating layer 192 may be positioned on a level higher than those of the stack structure and the cell region insulating layer 190. The first upper insulating layer 192 may have a conformal thickness and extend in the X-direction and the Y-direction. A thickness of the first upper insulating layer 192 may be substantially equal to or less than a thickness of the first gate electrode 130. The first upper insulating layer 192 may include a material different from that of the cell region insulating layer 190. The first upper insulating layer 192 may include a material having etch selectivity with the cell region insulating layer 190. For example, the first upper insulating layer 192 may include at least one of nitride-based materials such as silicon nitride and silicon oxynitride. The upper surface of the first channel pad 145 may be positioned on a level the same as or substantially similar to that of the upper surface of the cell region insulating layer 190, and may be in contact with a lower surface of the first upper insulating layer 192.

The second gate electrode 150 may be disposed on the first upper insulating layer 192. The second gate electrode 150 may be positioned on a level higher than that of the first channel structures CH1. The second gate electrode 150 may be spaced apart from the cell region insulating layer 190 by the first upper insulating layer 192. The first upper insulating layer 192 may include, for example, silicon oxide. A thickness of the second gate electrode 150 may be greater than a thickness of each of the first gate electrodes 130. In an example embodiment, the second gate electrode 150 may include a material different from that of the first gate electrodes 130. For example, the second gate electrode 150 may be a semiconductor material layer such as polycrystalline silicon. However, the second gate electrode 150 may include at least one of a doped semiconductor material, a metal (for example, TiN or TaN), and a transition metal (for example, Ti or Ta). The second gate electrode 150 may be a string selection gate electrode forming a string selection transistor.

The second to fourth upper insulating layers 193, 194, and 195 may be sequentially stacked on the second gate electrode 150. The first to fourth upper insulating layers 192, 193, 194, and 195 may include at least one of silicon oxide, silicon nitride, and silicon oxynitride.

The upper isolation regions SS may be disposed to pass through the second gate electrode 150 and extend in the X-direction. In an example embodiment, upper surfaces of the upper isolation regions SS may be positioned on a level the same as or substantially similar to that of an upper surface of the second gate electrode 150. The upper isolation regions SS may pass through the second gate electrode 150 and extend into the first upper insulating layer 192. Lower surfaces of the upper isolation regions SS may be positioned on a level higher than a lower surface of the first upper insulating layer 192.

The upper isolation regions SS may be positioned on a level higher than the isolation regions MS. In plan view, at least a portion of the upper isolation regions SS may overlap the isolation regions MS extending in the X-direction. A distance between adjacent isolation regions MS in the Y-direction may be greater than a distance between adjacent upper isolation regions SS in the Y-direction. Accordingly, in plan view, at least a portion of the upper isolation regions SS may be disposed between the adjacent isolation regions MS. As the upper isolation regions SS and the second gate electrode 150 are positioned on a level higher than the isolation regions MS and the first channel structures CH1, dummy structures between the first channel structures CH1 may be omitted, and the semiconductor device 100 having an improved degree of integration may be provided.

An upper isolation insulating layer 103 may be disposed in the upper isolation regions SS. In an example embodiment, the upper isolation insulating layer 103 may include an insulating material such as silicon oxide. However, in some example embodiments, the upper isolation regions SS may include at least a portion of materials of the second channel structures CH2.

The second channel structures CH2 may pass through the second gate electrode 150 and the first upper insulating layer 192 to be connected to the first channel pad 145. The second channel structures CH2 may be electrically connected to the first channel structures CH1 through the first channel pad 145, respectively. The second channel structures CH2 may be string selection channel structures, passing through the second gate electrode 150 forming a string selection transistor. Each of the second channel structures CH2 may have a columnar shape, and may have an inclined side surface such that a horizontal width of the second channel structures CH2 becomes narrower as a distance to the substrate 101 decreases depending on an aspect ratio.

The second channel structures CH2 may be disposed on the first upper insulating layer 192 in rows and columns to be spaced apart from each other, so as to correspond to the first channel structures CH1, respectively. The second channel structures CH2 may form a lattice pattern or have a zigzag shape in one direction, on an X-Y plane. Central axes of the second channel structures CH2 and central axes of the first channel structures CH1 may be aligned with each other. Each of the second channel structures CH2 may further include, in addition to the second channel layer 170, a second dielectric layer 172, a second buried insulating layer 174 between (e.g., surrounded by) the second channel layers 170, and a second channel pad 175 on the second buried insulating layer 174.

The second channel layer 170 may be formed to have an annular shape surrounding the second buried insulating layer 174 therein. However, in some example embodiments, the second channel layer 170 may have a columnar shape such as a cylinder or a prism, without the second buried insulating layer 174. A lower portion of the second channel layer 170 may be connected to the first channel pad 145. For example, the second channel layer 170 may be connected to the upper surface of the first channel pad 145 through a lower surface thereof. The second channel layer 170 may include a semiconductor material such as polycrystalline silicon or single crystal silicon, and the semiconductor material may be an undoped material or a material including P-type or N-type impurities.

The second dielectric layer 172 may be disposed between the second gate electrode 150 and the second channel layer 170. The second dielectric layer 172 may include, but is not limited to, silicon oxide, silicon nitride, silicon oxynitride, or a high-κ dielectric material.

The second buried insulating layer 174 may be disposed between (e.g., surrounded by) the second channel layers 170. The second buried insulating layer 174 may be disposed below the second channel pad 175. The second buried insulating layer 174 may have a shape having a width decreasing toward the first channel pad 145 due to a high aspect ratio. The second buried insulating layer 174 may include at least one of silicon oxide, silicon nitride, or silicon oxynitride.

The second channel pad 175 may be disposed to cover an upper surface of the second buried insulating layer 174 and to be electrically connected to the second channel layer 170. The second channel pad 175 may be disposed on an upper portion of the second channel layer 170. The second channel pad 175 may include, for example, polycrystalline silicon. According to an example embodiment, a width of each of the second channel structures CH2 may be less than that of each of the first channel structures CH1.

Upper surfaces of the second channel structures CH2 may be positioned on a level higher than that of an upper surface of each of the upper isolation regions SS.

The upper interconnection structure 180 may include a conductive material, and may be electrically connected to the first and second channel structures CH1 and CH2. The upper interconnection structure 180 may include studs 181, contact plugs 182, and an upper interconnection 183. The studs 181 may pass through a third upper insulating layer 194 to be in contact with the upper surfaces of the second channel structures CH2. The contact plugs 182 may pass through a fourth upper insulating layer 195 to be connected to the studs 181. The upper interconnection 183 may be disposed on the contact plugs 182 and the fourth upper insulating layer 195. At least a portion of the upper interconnection 183 may be bit lines in contact with the contact plugs 182 and the studs 181. The bit lines may be electrically connected to the second channel structures CH2 through the contact plugs 182, and thus may be electrically connected to the first channel structures CH1.

FIG. 2D is a schematic partially enlarged view of a semiconductor device according to an example embodiment. FIG. 2D illustrates a region corresponding to region “B” of FIG. 2A.

Referring to FIG. 2D, a semiconductor device 100a may further include a void 143 in a first buried insulating layer 144. The void 143 may be disposed to be spaced apart from a first channel pad 145. The void 143 may include air or gas formed of a material used in a process of manufacturing the semiconductor device 100a. The void 143 may be formed on an upper portion of the first buried insulating layer 144 in a process of forming the first buried insulating layer 144 to be described below.

FIG. 2E is a schematic partially enlarged view of a semiconductor device according to an example embodiment. FIG. 2E illustrates a region corresponding to region “B” of FIG. 2A.

Referring to FIG. 2E, in a semiconductor device 100b, the upper surface of a first dielectric layer 142 may be disposed on a level the same as or substantially similar to that of the upper surface of a first channel layer 140. For example, in the semiconductor device 100b, upper surfaces of the first channel layer 140, a tunneling layer 142a, a charge storage layer 142b, and a blocking layer 142c may be substantially coplanar.

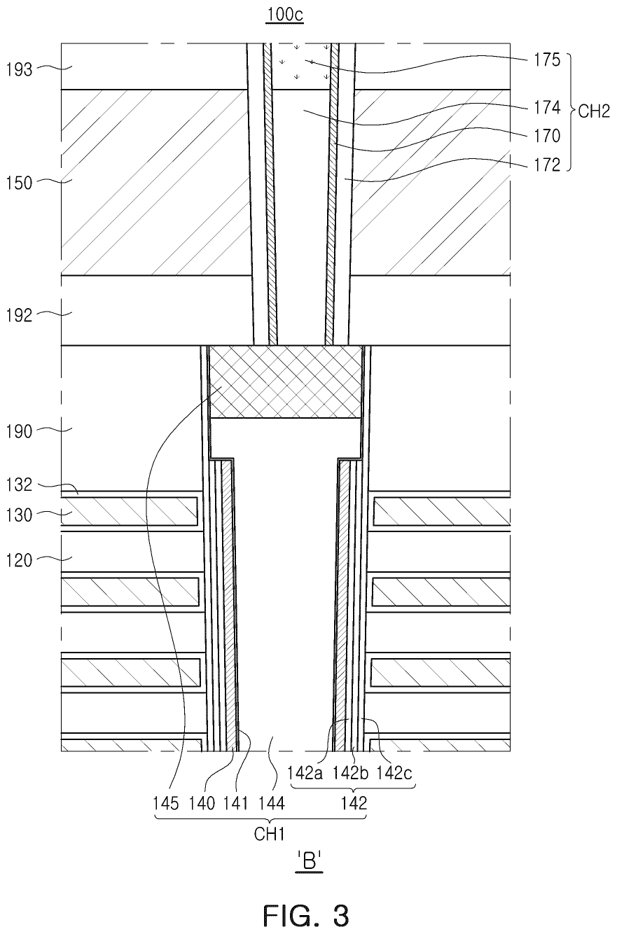

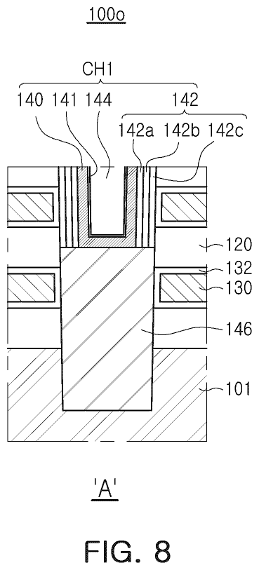

FIGS. 3 to 8 are partially enlarged schematic views of semiconductor devices according to some example embodiments. FIGS. 3 to 7 each illustrate a region corresponding to region “B” of FIG. 2A. FIG. 8 illustrates a region corresponding to region “A” of FIG. 2A.

Referring to FIG. 3, in a semiconductor device 100c, central axes of first channel structures CH1 and central axes of second channel structures CH2 may be shifted or offset from each other. For example, the central axes of the first channel structures CH1 and the central axes of the second channel structures CH2 may be misaligned with each other. However, even in the above-described case, a width of a first channel pad 145 may be wider than a width between external side surfaces of a first channel layer 140, such that a contact area with the second channel structures CH2 may be secured, and a misalignment margin between the first channel pad 145 and the second channel structures CH2 may be secured, thereby providing the semiconductor device 100c having an improved degree of integration and improved reliability.

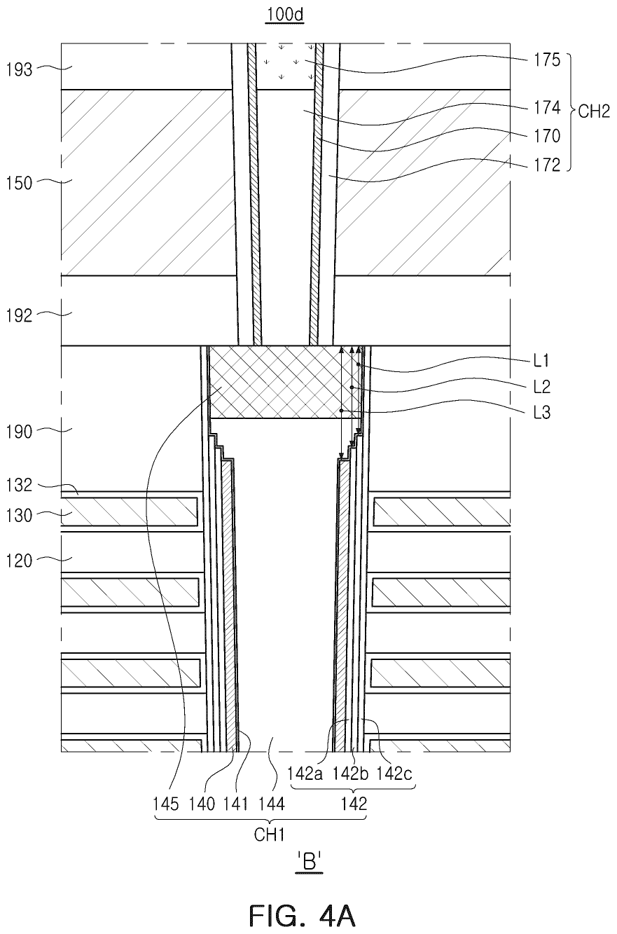

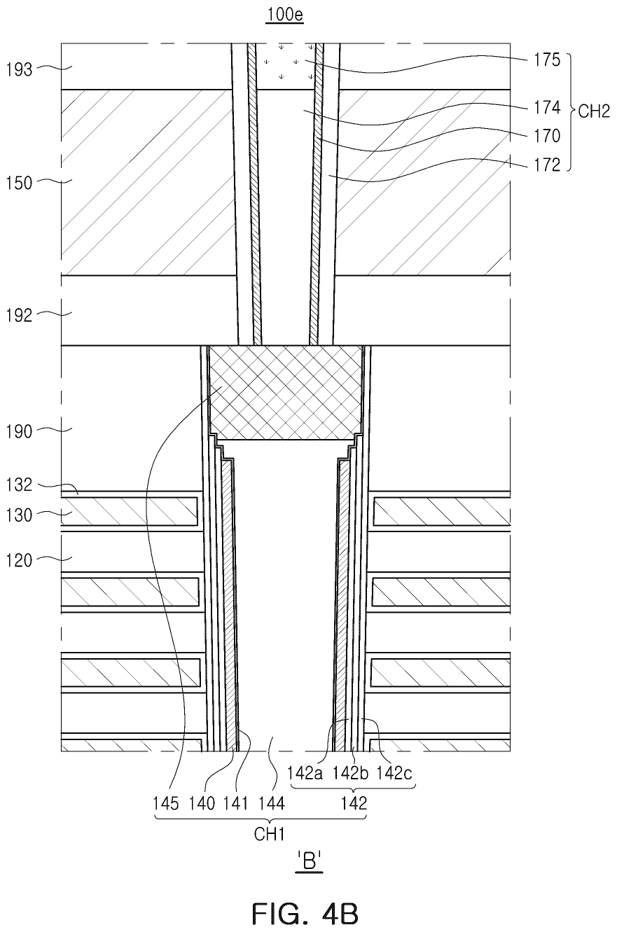

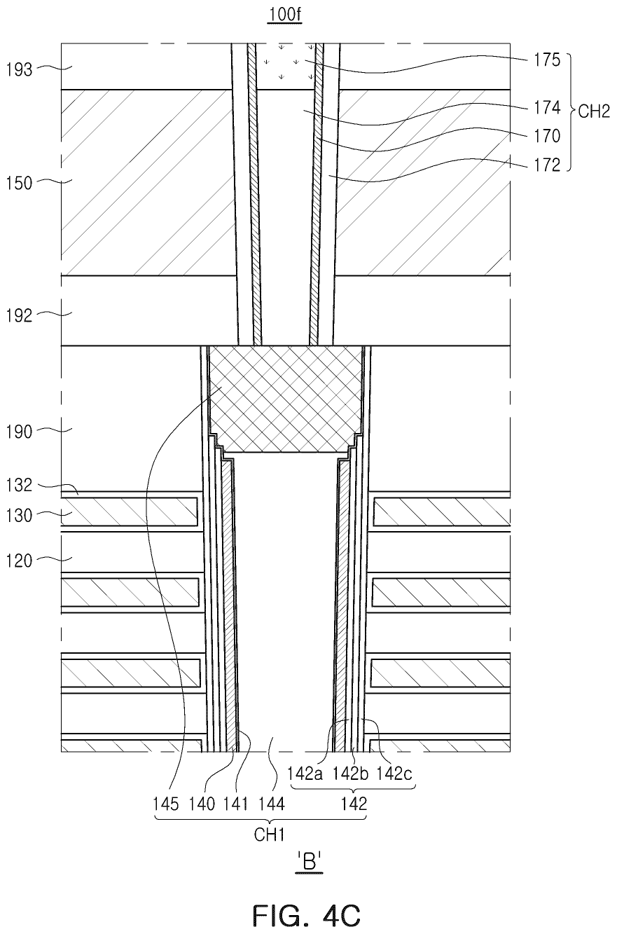

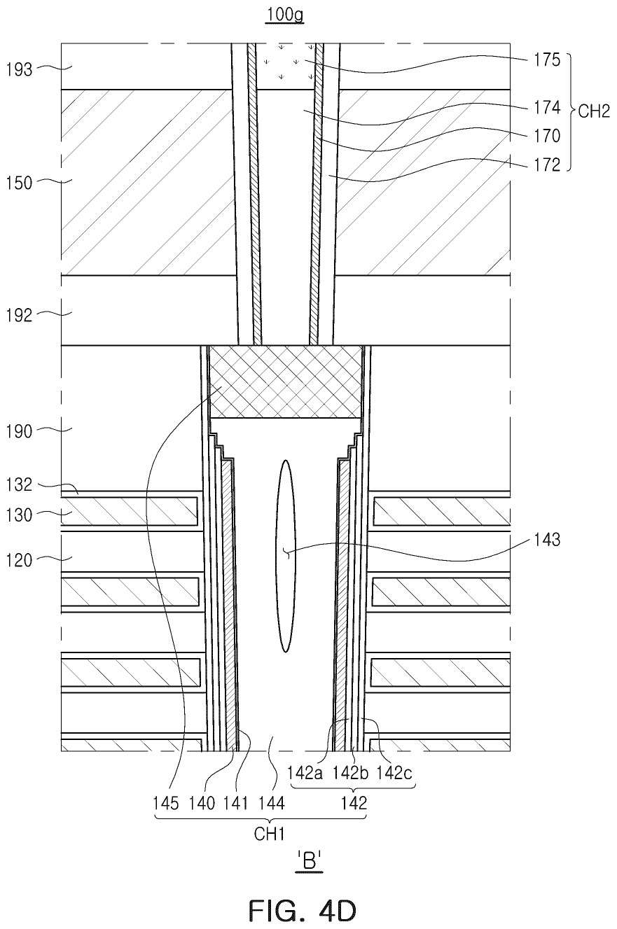

Referring to FIG. 4A, in a semiconductor device 100d, a first channel layer 140, a tunneling layer 142a, and a charge storage layer 142b may have a staircase structure. A first dielectric layer 142 may include first to third layers 142a, 142b, and 142c sequentially stacked from the first channel layer 140. The first to third layers 142a, 142b, and 142c may be the tunneling layer 142a, the charge storage layer 142b, and a blocking layer 142c, respectively. A length between an upper surface of a first channel pad 145 and an upper surface of the second layer 142b may be defined as a first length L1, a length between the upper surface of the first channel pad 145 and an upper surface of the first layer 142a may be defined as a second length L2, and a length between the upper surface of the first channel pad 145 and an upper surface of the first channel layer 140 may be defined as a third length L3.

According to an example embodiment, the first length L1 may be less than or equal to the second length L2, and the second length L2 may be less than or equal to the third length L3. For example, the first length L1 may be less than the second length L2, and the second length L2 may be less than the third length L3. A lower surface of the first channel pad 145 may be positioned on a level higher than an upper surface of the second layer 142b. An upper surface of the third layer 142c may be coplanar with an upper surface of an auxiliary channel layer 141 and the upper surface of the first channel pad 145, but example embodiments of the present disclosure are not limited thereto. A lower surface of the first channel pad 145 may be positioned on a level higher than those of the upper surfaces of the first channel layer 140, the first layer 142a, and the second layer 142b.

Referring to FIG. 4B, in a semiconductor device 100e, unlike the semiconductor device 100d of FIG. 4A, a lower surface of a first channel pad 145 may be positioned between an upper surface of a first layer 142a and an upper surface of a second layer 142b. In addition, descriptions overlapping those described with reference to FIG. 4A will be omitted.

Referring to FIG. 4C, in a semiconductor device 100f, unlike the semiconductor device 100d of FIG. 4A, a lower surface of a first channel pad 145 may be positioned between an upper surface of a first layer 142a and an upper surface of a first channel layer 140. In addition, descriptions overlapping those described with reference to FIG. 4A will be omitted.

Referring to FIG. 4D, in a semiconductor device 100g, first channel structures CH1 may have a structure the same as that of FIG. 4A, and may further include a void 143, which is also applicable to other example embodiments. The void 143 may be understood as having a characteristic the same as or substantially similar to that of the void 143 of the above-described example embodiment of FIG. 2D.

In the following description of the example embodiment, a description overlapping with the above description will be omitted.

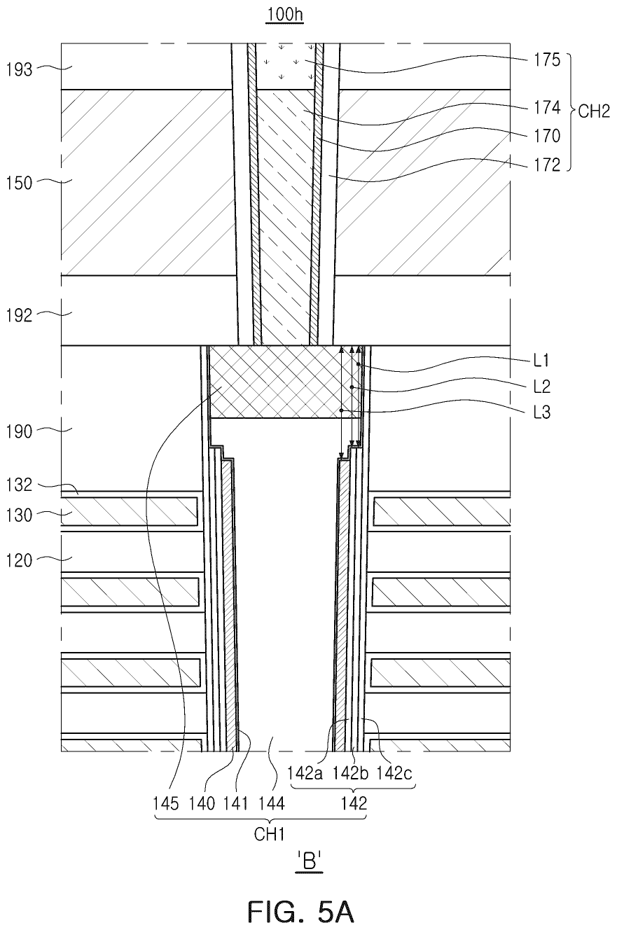

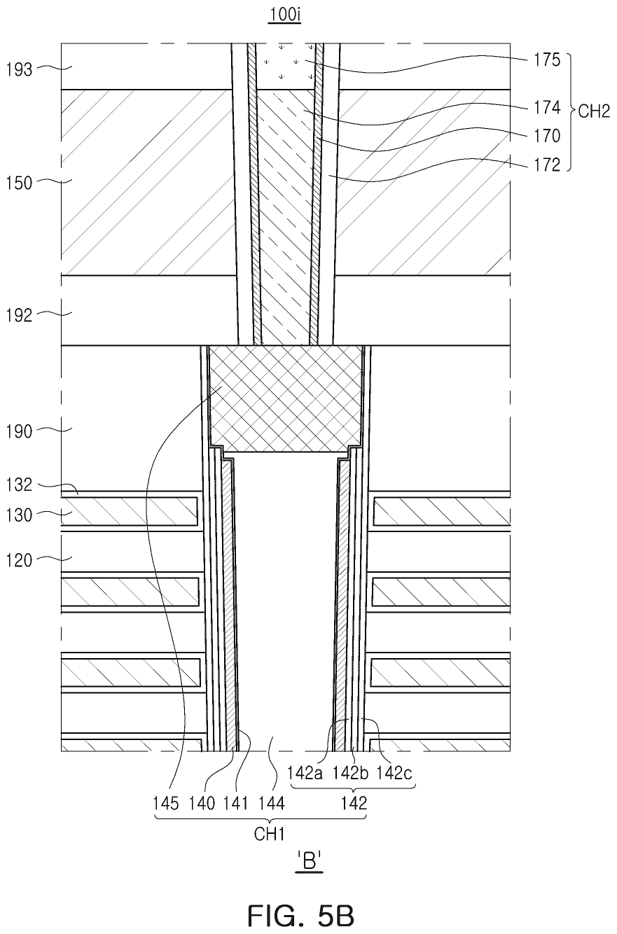

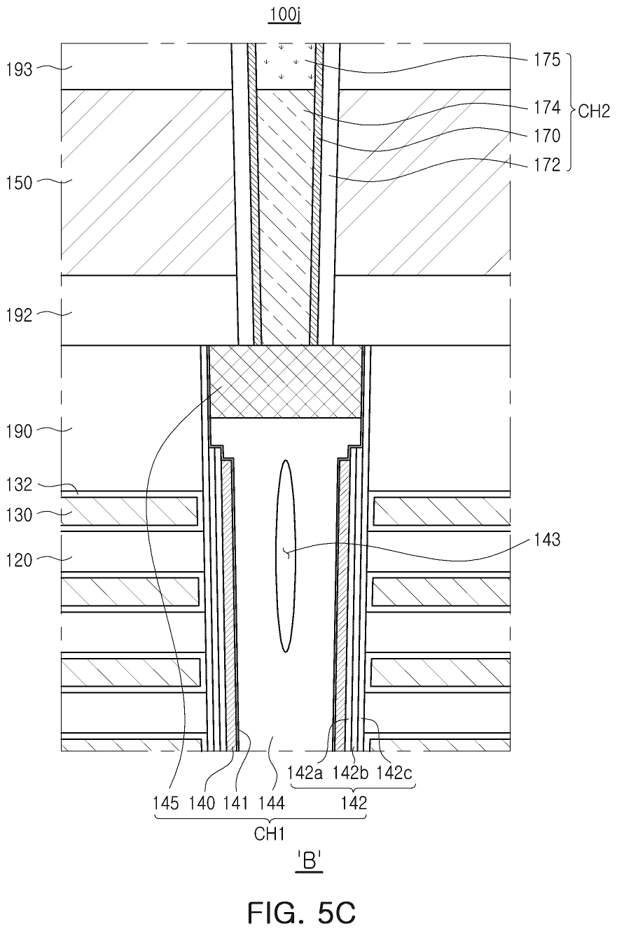

Referring to FIG. 5A, in a semiconductor device 100h, a first length L1 may be substantially equal to a second length L2, and the second length L2 may be less than a third length L3. Thus, an upper surface of a first layer 142a and an upper surface of a second layer 142b may be coplanar. A lower surface of a first channel pad 145 may be positioned on a level higher than those of upper surfaces of a first channel layer 140, the first layer 142a, and the second layer 142b.

Referring to FIG. 5B, in a semiconductor device 100i, a first layer 142a and a second layer 142b may be disposed in the same manner as in the example embodiment of FIG. 5A. Thus, a lower surface of a first channel pad 145 may be positioned between an upper surface of the first layer 142a and an upper surface of a first channel layer 140. In addition, the lower surface of the first channel pad 145 may be positioned between an upper surface of the second layer 142b and the upper surface of the first channel layer 140.

Referring to FIG. 5C, in a semiconductor device 100j, a first channel structure CH1 may have a structure the same as that of FIG. 5A, and may further include a void 143, which is also applicable to some other example embodiments. The void 143 may be understood as having a characteristic the same as or substantially similar to that of the void 143 of FIG. 2D.

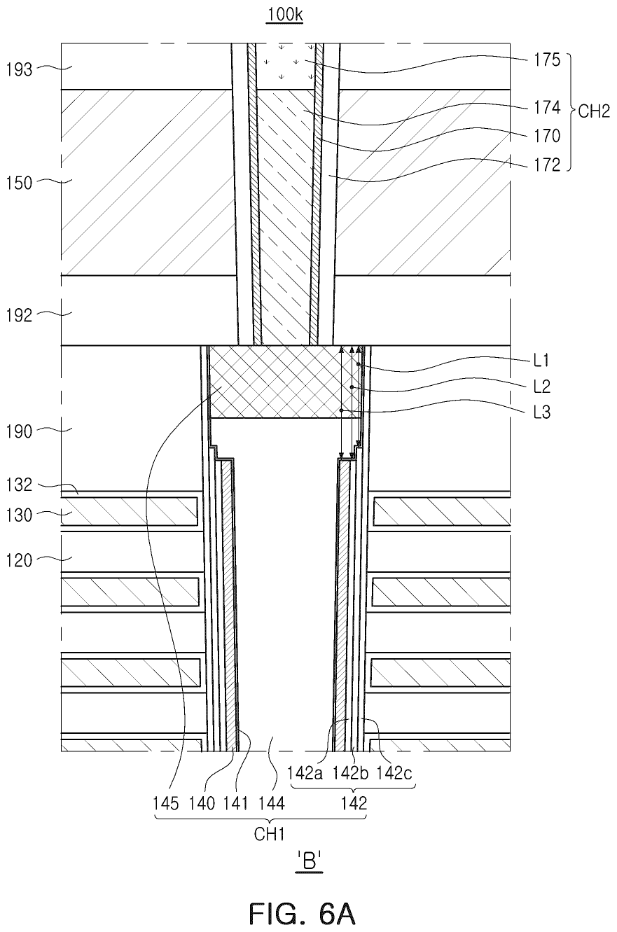

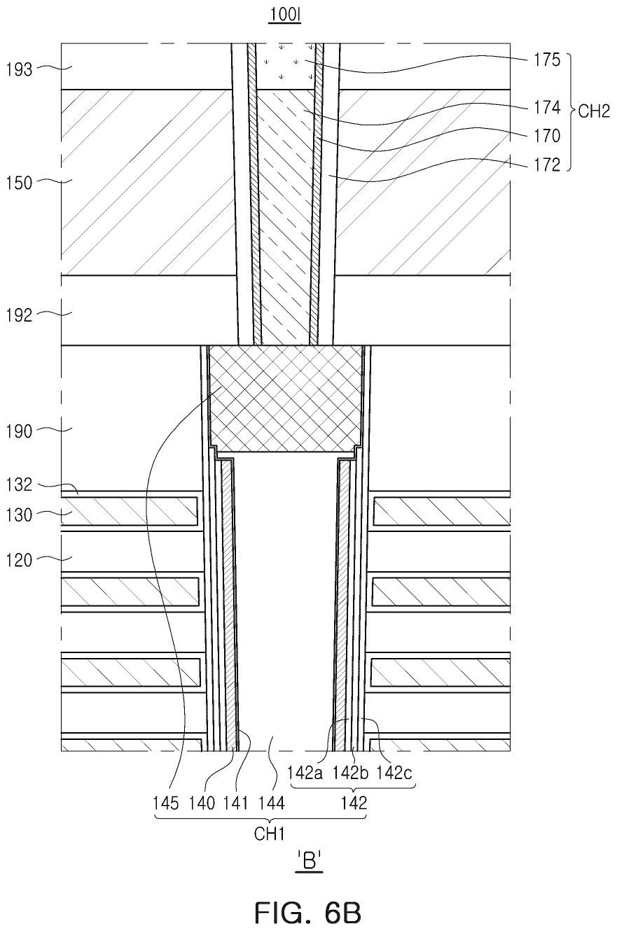

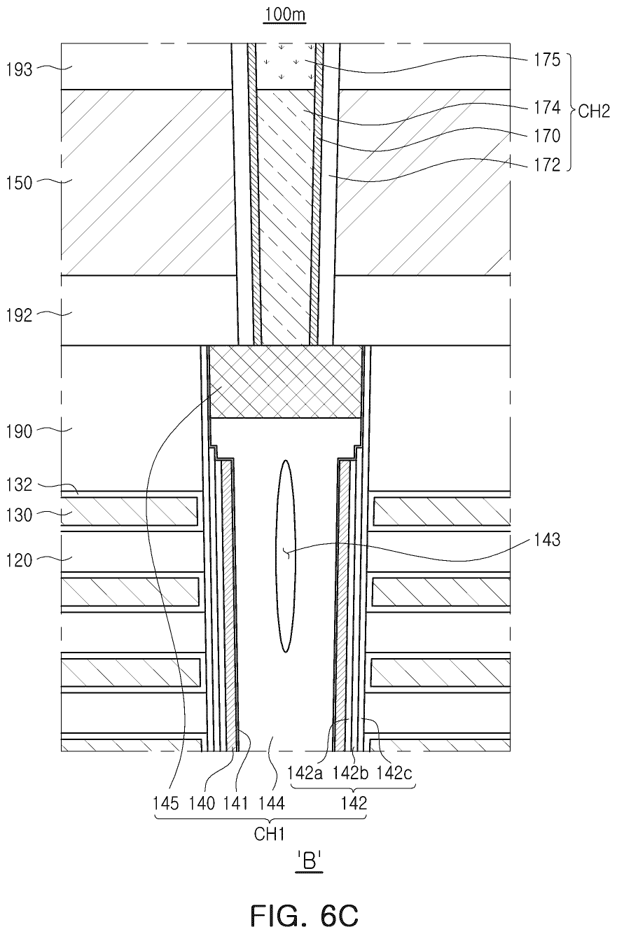

Referring to FIG. 6A, in a semiconductor device 100k, a first length L1 may be less than a second length L2, and the second length L2 may be equal to or substantially similar to a third length L3. Thus, an upper surface of a first channel layer 140 and an upper surface of a first layer 142a may be coplanar. A lower surface of a first channel pad 145 may be positioned on a level higher than those of upper surfaces of the first channel layer 140, the first layer 142a, and a second layer 142b.

Referring to FIG. 6B, in a semiconductor device 100l, a lower surface of a first channel pad 145 may be positioned between an upper surface of a second layer 142b and an upper surface of a first channel layer 140. In addition, the lower surface of the first channel pad 145 may be positioned between the upper surface of the second layer 142b and an upper surface of a first layer 142a.

Referring to FIG. 6C, in a semiconductor device 100m, a first channel structure CH1 may have a structure the same as that of FIG. 6A, and may further include a void 143, which is also applicable to some other example embodiments. The void 143 may be understood as having a characteristic the same as or substantially similar to that of the void 143 of FIG. 2D.

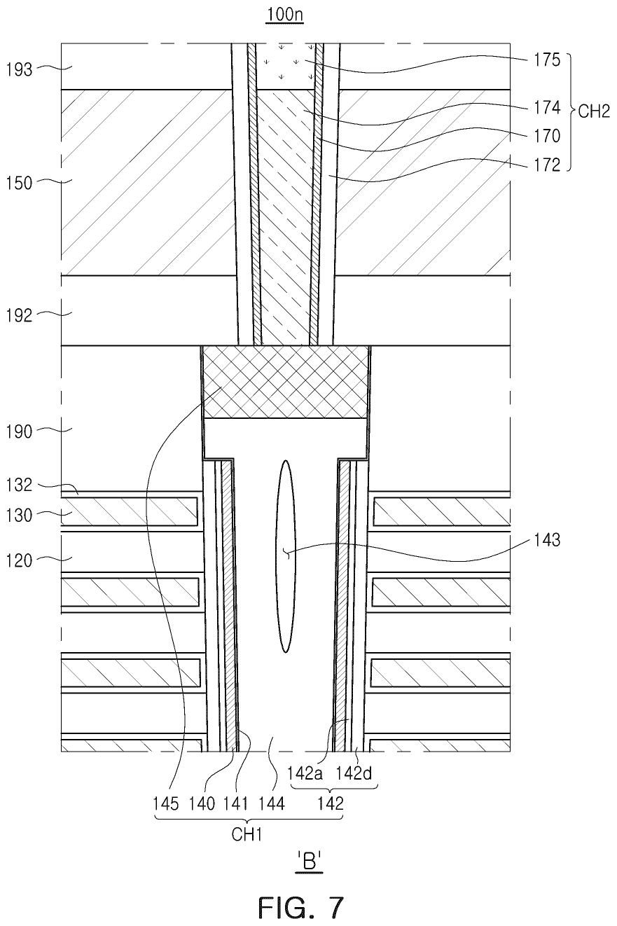

Referring to FIG. 7, in a semiconductor device 100n, a first dielectric layer 142 may include a first layer 142a and a ferroelectric layer 142d. The ferroelectric layer 142d, which may be formed of a ferroelectric material, may have polarization characteristics depending on an electric field applied by a gate electrode 130, and may have remnant polarization by a dipole even in the absence of an external electric field. The ferroelectric material may include at least one of an Hf-based compound, a Zr-based compound, and an Hf—Zr-based compound. For example, the Hf-based compound may be an HfO-based ferroelectric material, the Zr-based compound may include a ZrO-based ferroelectric material, and the Hf—Zr-based compound may be a hafnium zirconium oxide (HZO)-based ferroelectric material.

A first channel structure CH1 may further include a void 143, but example embodiments of the present disclosure are not limited thereto.

Referring to FIG. 8, unlike FIG. 2B, a semiconductor device 1000 may include a first channel structures CH1 having a different lower structure. The first channel structures CH1 may include an epitaxial layer 146, a first channel layer 140, an auxiliary channel layer 141, a first dielectric layer 142, and a first buried insulating layer 144. The epitaxial layer 146 may be disposed on the substrate 101 at a lower end of the first channel structures CH1, and may be disposed on a side surface of at least one first gate electrode 130. An insulating layer may be further disposed between the epitaxial layer 146 and the side surface of the first gate electrode 130. The epitaxial layer 146 may be disposed in a recessed region of the substrate 101. An upper surface of the epitaxial layer 146 may be higher than an upper surface of a first lowermost gate electrode 130, and may be lower than a lower surface of a first gate electrode 130 on the first lowermost gate electrode 130, but example embodiments of the present disclosure are not limited thereto. In some example embodiments, the epitaxial layer 146 may be omitted. In this case, the first channel layer 140 may be directly connected to a substrate 101.

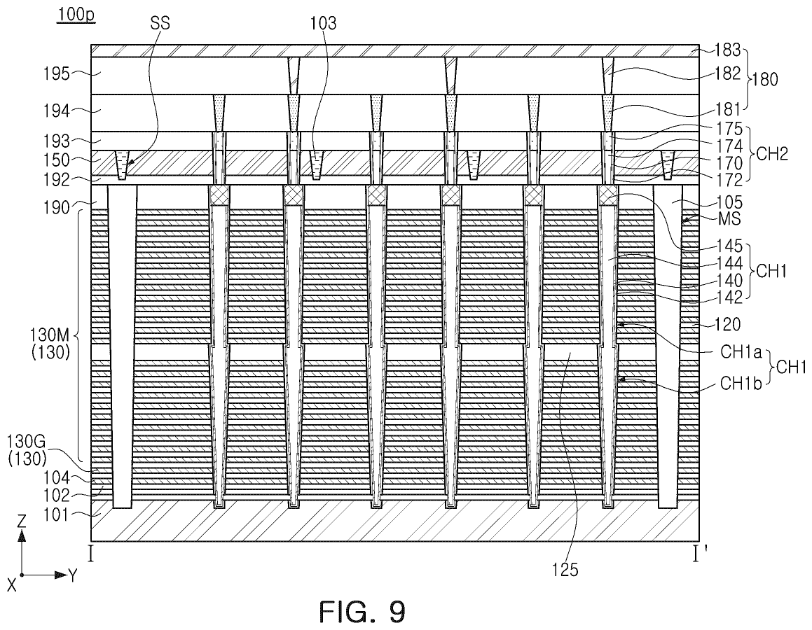

FIGS. 9 to 11 are schematic cross-sectional views of a semiconductor device according to some example embodiments. FIGS. 9 to 11 each illustrate a region corresponding to a cross-section taken along line I-I′ of FIG. 1.

Referring to FIG. 9, in a semiconductor device 100p, a stack structure of first gate electrodes 130 each may include vertically stacked lower and upper stack structures, and the first channel structures CH1 each may include vertically stacked lower and upper channel structures CH1a and CH1b. Accordingly, the first channel structures CH1 may be stably formed when the number of the stacked first gate electrodes 130 is relatively large. In some example embodiments, the number of stacked first channel structures may be changed in various manners.

The first channel structures CH1 may have a form in which the lower channel structures CH1a and the upper channel structures CH1b are connected to each other, and may have a bent portion caused by a difference in width in a connection region. A first channel layer 140, an auxiliary channel layer 141, a first dielectric layer 142, and a first buried insulating layer 144 may be connected to each other between the lower channel structure CH1a and the upper channel structure CH1b. A first channel pad 145 may be disposed only at an upper end of the upper channel structure CH1b. However, in some example embodiments, the lower channel structure CH1a and the upper channel structure CH1b may include the first channel pad 145, respectively. In this case, the first channel pad of the lower channel structure CH1a 145 may be connected to the first channel layer 140 of the upper channel structure CH1b. A relatively thick upper interlayer insulating layer 125 may be disposed on an uppermost portion of the lower stack structure. However, in some example embodiments, forms of interlayer insulating layers 120 and the upper interlayer insulating layer 125 may be changed in various manners. Thus, the form of the plurality of stacked first channel structures CH1 may also be applicable to some other example embodiments.

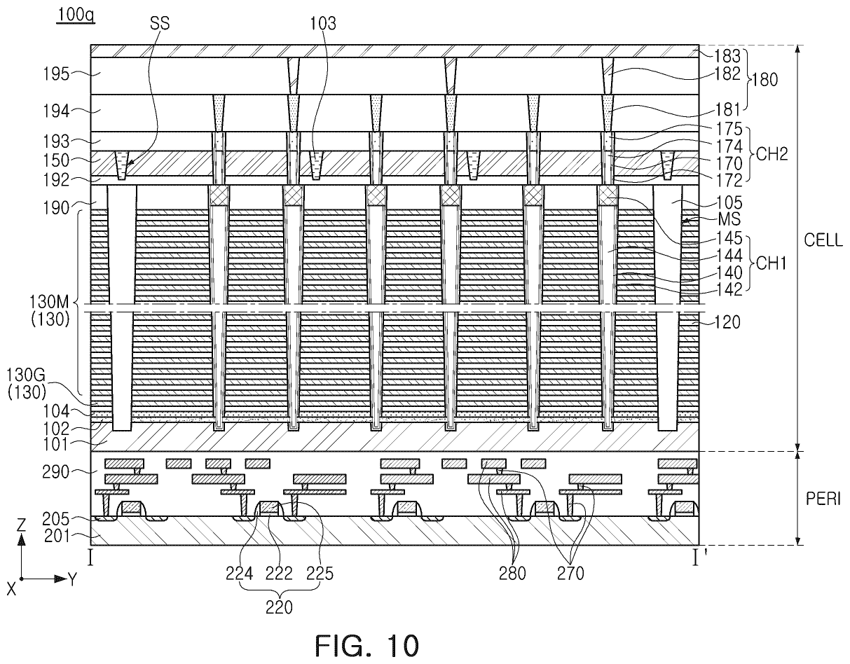

Referring to FIG. 10, a semiconductor device 100q may include a memory cell region CELL and a peripheral circuit region PERI stacked vertically. The memory cell region CELL may be disposed at an upper end of the peripheral circuit region PERI. For example, in the semiconductor device 100 of FIG. 2A, the peripheral circuit region PERI may be disposed on a substrate 101 in a region not illustrated, or the peripheral circuit region PERI may be disposed on a lower portion of the memory cell region CELL as in the semiconductor device 100q of the present example embodiment. In some example embodiments, the cell region CELL may be disposed at a lower end of the peripheral circuit region PERI and the description provided with reference to FIGS. 1 to 2D may be applicable to the memory cell region CELL.

The peripheral circuit region PERI may include a base substrate 201, circuit elements 220 disposed on the base substrate 201, circuit contact plugs 270, and circuit interconnection lines 280.

The base substrate 201 may have upper surfaces extending in an X-direction and a Y-direction. The base substrate 201 may have device isolation layers formed thereon to define an active region. Source/drain regions 205 including impurities may be disposed in a portion of the active region. The base substrate 201 may include a semiconductor material, for example, a group IV semiconductor, a group III-V compound semiconductor, or a group II-VI compound semiconductor. The base substrate 201 may be provided as a bulk wafer or an epitaxial layer. In the present example embodiment, an upper substrate 101 may be provided as a polycrystalline semiconductor layer such as a polycrystalline silicon layer, or an epitaxial layer.

The circuit elements 220 may include a horizontal transistor. Each of the circuit elements 220 may include a circuit gate dielectric layer 222, a spacer layer 224 and a circuit gate electrode 225. At opposite sides of the circuit gate electrode 225, the source/drain regions 205 may be disposed in the base substrate 201.

On the base substrate 201, a peripheral region insulating layer 290 may be disposed on the circuit element 220. The circuit contact plugs 270 may pass through the peripheral insulating layer 290 to be connected to the source/drain regions 205. An electrical signal may be applied to the circuit element 220 by the circuit contact plugs 270. In a region not illustrated, circuit contact plugs 270 may also be connected to the circuit gate electrode 225. Circuit interconnection lines 280 may be connected to the circuit contact plugs 270, and may be disposed in a plurality of layers.

In a semiconductor device 200, the peripheral circuit region PERI may be manufactured first, and then the substrate 101 of memory cell region CELL may be formed thereon to form the memory cell region CELL. The substrate 101 may have a size the same as or substantially similar to that of the base substrate 201 or a size smaller than that of the base substrate 201. The memory cell region CELL and the peripheral circuit region PERI may be connected to each other in a region not illustrated. For example, one end of the gate electrode 130 in the Y-direction may be electrically connected to the circuit elements 220. A form in which the memory cell region CELL and the peripheral circuit region PERI are vertically stacked may also be applied to the example embodiments of FIGS. 1 to 9.

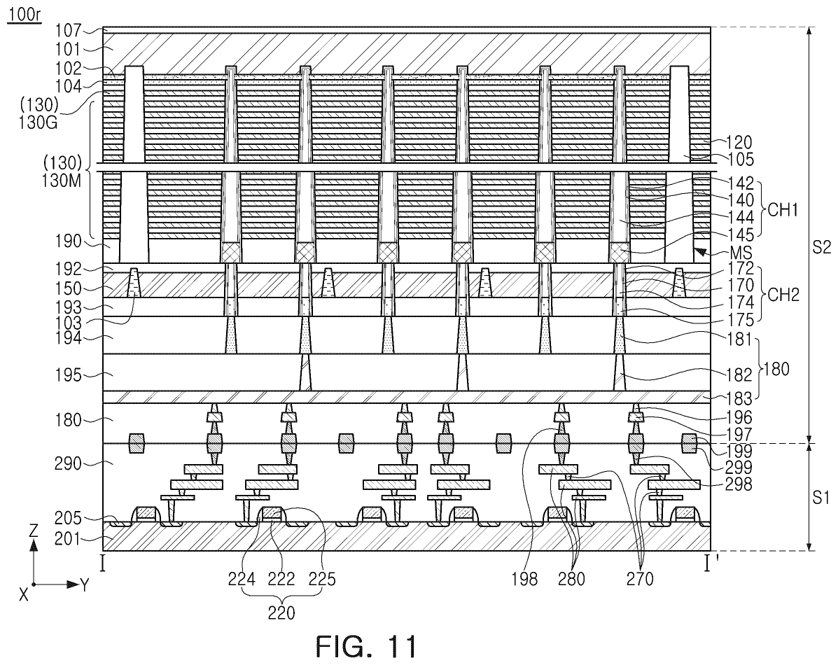

Referring to FIG. 11, a semiconductor device 100r may include a first structure S1 and a second structure S2 bonded to each other by a wafer bonding method.

With respect to the first structure S1, the description of the peripheral circuit region PERI provided above with reference to FIG. 10 may be applied. However, the first structure S1 may further include first bonding vias 298 and first bonding pads 299. The first bonding vias 298 may be disposed an upper portion of uppermost circuit interconnection lines 280 to be connected to the circuit interconnection lines 280. At least some of the first bonding pads 299 may be connected to corresponding ones of the first bonding vias 298 on the first bonding vias 298, respectively. The first bonding pads 299 may be connected to the second bonding pads 199 of the second structure S2. The first bonding pads 299 may provide an electrical connection path by bonding of the first structure S1 and the second structure S2, together with the second bonding pads 199. The first bonding vias 298 and the first bonding pads 299 may include a conductive material, such as copper (Cu).

With respect to the second structure S2, unless otherwise described, the description provided with reference to FIGS. 1 to 2D may be applied in the same manner. An upper interconnection structure of the second structure S2 may further include a conductive through via 196 and a conductive line 197 connected to the upper interconnection 183. The conductive line 197 may include a plurality of conductive lines disposed on different levels, unlike that illustrated. In addition, the second structure S2 may further include second bonding vias 198 and second bonding pads 199. The second structure S2 may further include a protective layer 107 covering an upper surface of the substrate 101.

The second bonding vias 198 and the second bonding pads 199 may be disposed on a lower portion of a lowermost conductive line 197. The second bonding vias 198 may be connected to the conductive line 197 and the second bonding pads 199, and the second bonding pads 199 may be connected to the first bonding pads 299 of the first structure S1. The second bonding vias 198 and the second bonding pads 199 may include a conductive material, such as copper (Cu).

The first structure S1 and the second structure S2 may be bonded by copper (Cu)-copper (Cu) bonding by the first bonding pads 299 and the second bonding pads 199. In addition to the copper (Cu)-copper (Cu) bonding, the first structure S1 and the second structure S2 may be additionally bonded by dielectric-dielectric bonding. The dielectric-dielectric bonding may be bonding by dielectric layers forming a portion of each of the peripheral region insulating layer 290 and the cell region insulating layer 180 and surrounding each of the first bonding pads 299 and the second bonding pads 199. Accordingly, the first structure S1 and the second structure S2 may be bonded to each other without an adhesive layer.

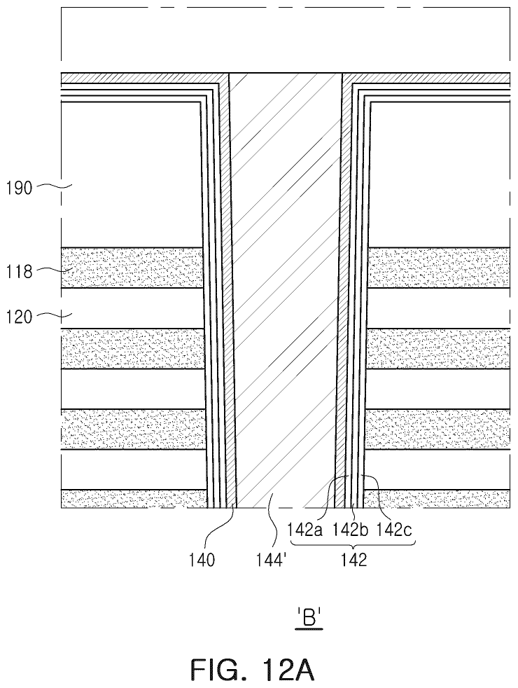

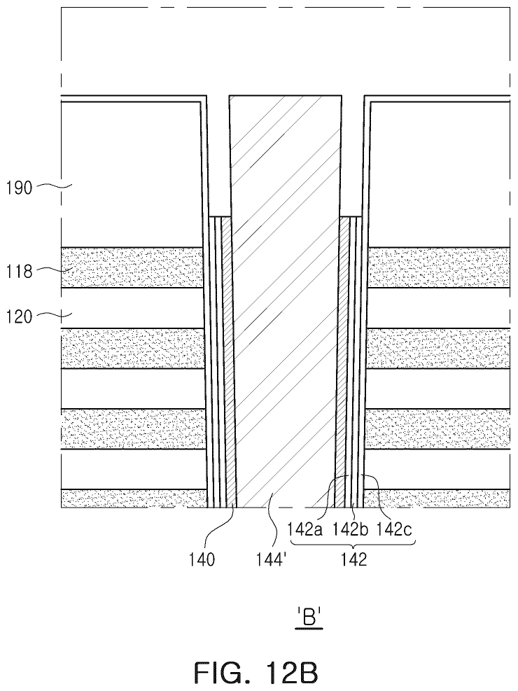

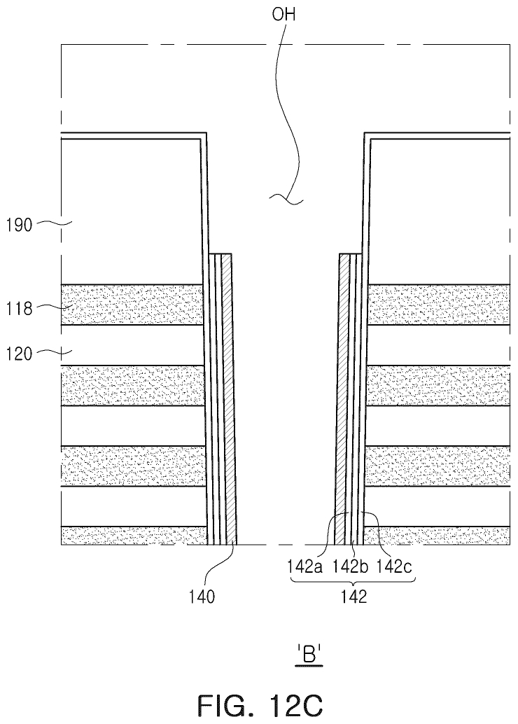

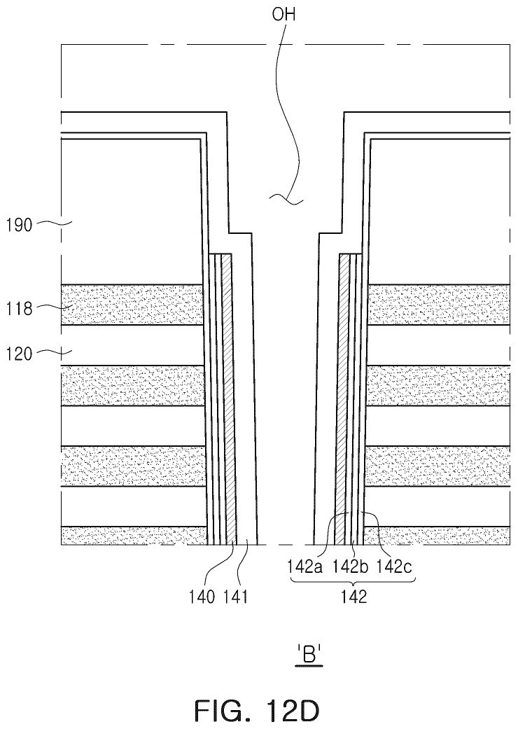

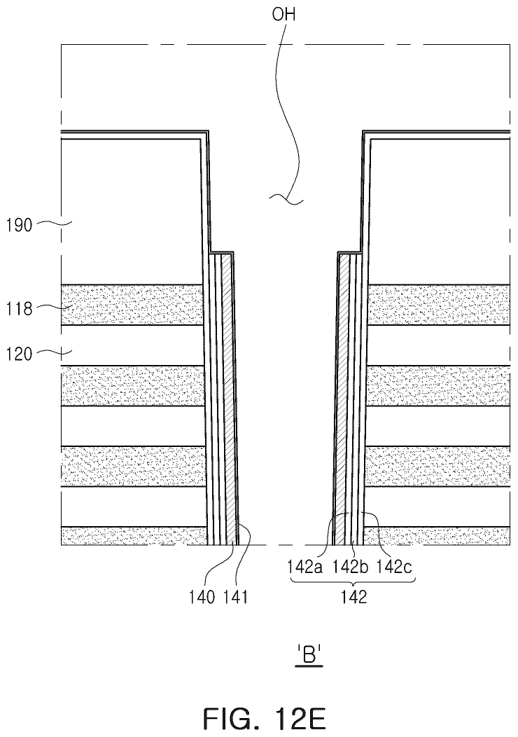

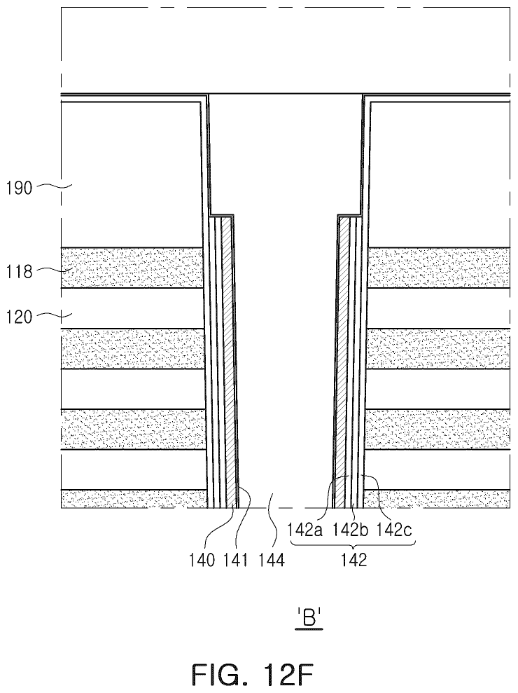

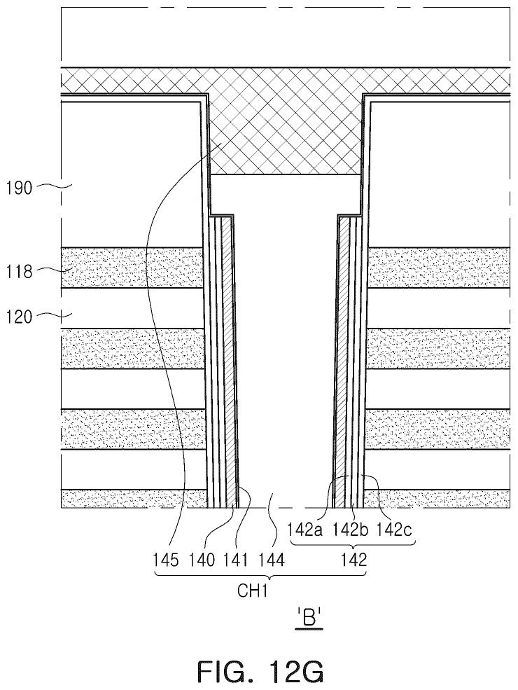

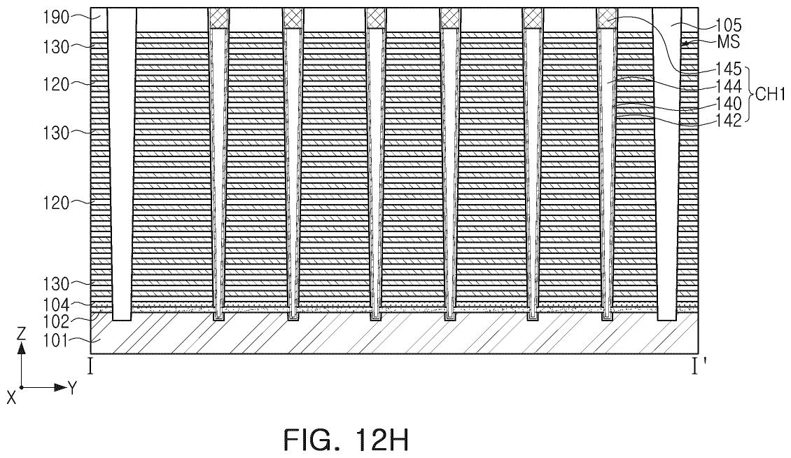

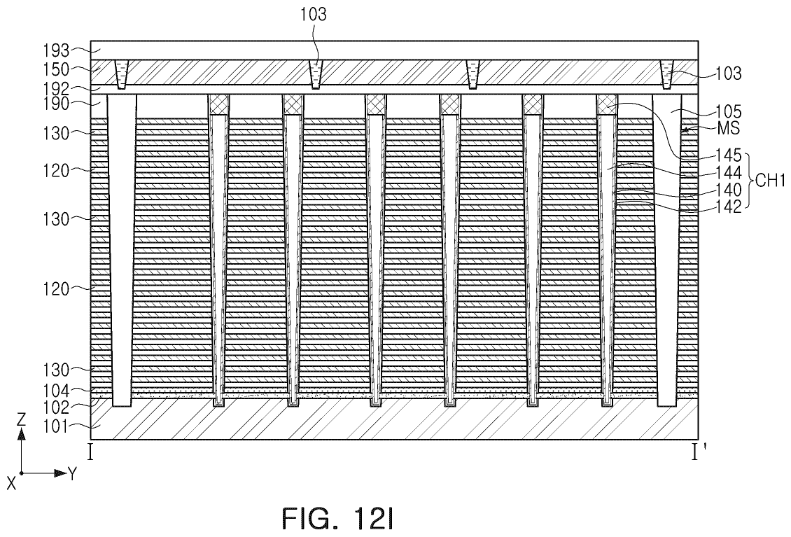

FIGS. 12A to 12I are schematic cross-sectional views and partially enlarged views illustrating a method of manufacturing a semiconductor device according to an example embodiment. In FIGS. 12A to 12G, regions corresponding to region “B” of FIG. 2A are illustrated. In FIGS. 12H and 12I, regions corresponding to that of FIG. 2A are illustrated.

Referring to FIG. 12A, horizontal sacrificial layers and the second horizontal conductive layer 104 (see FIG. 2B) may be formed on the substrate 101 (see FIG. 2A), and sacrificial insulating layers 118 and the interlayer insulating layers 120 may be alternately stacked to form the first channel structures CH1.

The horizontal sacrificial layers may include first to third horizontal sacrificial layers sequentially formed on the substrate 101. The second horizontal sacrificial layer may include a material different from those of the first horizontal sacrificial layer and the third horizontal sacrificial layer. The horizontal sacrificial layers may be layers replaced with the first horizontal conductive layer 102 (see FIG. 2A) through a subsequent process. For example, the first and third horizontal sacrificial layers may be formed of a material the same as that of the interlayer insulating layers 120, and the second horizontal sacrificial layer may be formed of a material the same as that of the sacrificial insulating layers 180. The second horizontal conductive layer 104 may be formed on the horizontal sacrificial layers.

A portion of the sacrificial insulating layers 118 may be replaced with the first gate electrodes 130 (see FIG. 2A) through a subsequent process. The sacrificial insulating layers 118 may be formed of a material different from that of the interlayer insulating layers 120, and may be formed of a material that may be etched with etch selectivity with respect to the interlayer insulating layers 120 under specific etching conditions. For example, the interlayer insulating layer 120 may be formed of at least one of silicon oxide and silicon nitride, and the sacrificial insulating layers 118 may be formed of a material which is selected from silicon, silicon oxide, silicon carbide, and silicon nitride, and is different from that of the interlayer insulating layers 120. In some example embodiments, the interlayer insulating layers 120 may not all have the same thickness. The thicknesses of the interlayer insulating layers 120 and the sacrificial insulating layers 118 and the number of constituent films of the interlayer insulating layers 120 and the sacrificial insulating layers 118 may be changed from those illustrated in various manners.

Subsequently, the cell region insulating layer 190, covering a stack structure of the sacrificial insulating layers 118 and the interlayer insulating layers 120, may be partially formed, and an opening corresponding to the first channel structures CH1 (see FIG. 2C) may be formed. The opening may be provided in the form of a hole by anisotropically etching the sacrificial insulating layers 118 and the interlayer insulating layers 120 using a mask layer. Due to a height of the stack structure, a sidewall of the opening may not be perpendicular to an upper surface of the substrate 101. The opening may be formed to recess a portion of the substrate 101. Subsequently, the first dielectric layer 142, the first channel layer 140, and a first preliminary buried insulating layer 144′ may be sequentially formed in the opening. The first dielectric layer 142 may be formed to have a uniform thickness using an ALD or CVD process. The first channel layer 140 may be formed on the first dielectric layer 142 in the first channel structures CH1. The first preliminary buried insulating layer 144′ may formed to fill the first channel structures CH1, and may include an insulating material. For example, the first preliminary buried insulating layer 144′ may be a spin-on hardmask (SOH).

Referring to FIG. 12B, the first channel layer 140, the tunneling layer 142a, and the charge storage layer 142b may be partially removed.

The blocking layer 142c may not be removed, but example embodiments of the present disclosure are not limited thereto. The blocking layer 142c may be removed in a process of manufacturing the semiconductor device 100b of FIG. 2E. The first channel layer 140, the tunneling layer 142a, and the charge storage layer 142b may be selectively removed with respect to the first preliminary buried insulating layer 144′. Upper surfaces of the first channel layer 140, the tunneling layer 142a, and the charge storage layer 142b may be at the same or substantially similar level, but example embodiments of the present disclosure are not limited thereto. The upper surfaces of the first channel layer 140, the tunneling layer 142a, and the charge storage layer 142b may have a step. The upper surfaces of the first channel layer 140, the tunneling layer 142a, and the charge storage layer 142b may be disposed on a level a higher than that of an upper surface of an uppermost sacrificial insulating layer 118 among the sacrificial insulating layers 188.

Referring to FIG. 12C, a vertical opening OH may be formed by removing the first preliminary buried insulating layer 144′.

The first preliminary buried insulating layer 144′ may be selectively removed with respect to the first dielectric layer 142. Thus, the vertical opening OH may be formed.

Referring to FIG. 12D, an auxiliary channel layer 141 may be formed in the vertical opening OH.

The auxiliary channel layer 141 may be formed by an atomic layer deposition (ALD) method. The auxiliary channel layer 141 may have a desired (or alternatively, predetermined) thickness along a side surface of the vertical opening OH. That is, the auxiliary channel layer 141 may conformally cover the first channel layer 140 and the first dielectric layer 142. The thickness of the auxiliary channel layer 141 may be greater than those of the first channel layer 140 and the first dielectric layer 142, but example embodiments of the present disclosure are not limited thereto. As illustrated in FIG. 12E, the thickness of the auxiliary channel layer 141 may be less than those of the first channel layer 140 and the first dielectric layer 142, as desired, without performing a trimming process of FIG. 12E to be described below.

Referring to FIG. 12E, the auxiliary channel layer 141 may be partially removed in the vertical opening OH.

The thickness the auxiliary channel layer 141 may be formed to be greater than a desired final thickness, and then may be adjusted to the desired final thickness through the trimming process. The thickness the auxiliary channel layer 141 may be formed to be less than that of the first channel layer 140 using, for example, the trimming process. The trimming process may be precisely performed using a solution such as an SC1 solution. The SC1 solution may be a mixed solution of deionized water, NH₄OH, and H₂O₂ at a ratio of 5:1:1. However, the above process may not be an essential process, and may be selectively performed. Accordingly, in FIG. 12D, the auxiliary channel layer 141 may be formed to have the desired final thickness. That is, the thickness of the auxiliary channel layer 141 may be formed to be less than those of the first channel layer 140 and the first dielectric layer 142, without performing the trimming process of FIG. 12E.

Referring to FIG. 12F, the first buried insulating layer 144 may fill the vertical opening OH.

A void 143 (see FIG. 2D) may be formed in a process of forming the first buried insulating layer 144, but example embodiments of the present disclosure are not limited thereto. The first buried insulating layer 144 may include, for example, silicon oxide, but example embodiments of the present disclosure are not limited thereto.

Referring to FIG. 12G, a portion of the first buried insulating layer 144 may be recessed, and the first channel pad 145 may be formed in a recess region.

The first channel pad 145 may be formed by an ALD method. A lower surface of the first channel pad 145 may be positioned on a level higher than that of an upper surface of the first channel layer 140. The first channel pad 145 may be in contact with the auxiliary channel layer 141. Accordingly, the first channel pad 145 may be electrically connected to the first channel layer 140 through the auxiliary channel layer 141.

Subsequently, as a planarization process is performed, the first channel structure CH1 may be formed by partially removing the first channel pad 145, the auxiliary channel layer 141, and the blocking layer 142c.

Referring to FIG. 12H, the first horizontal conductive layer 102, the first gate electrodes 130, and the isolation insulating layer 105 may be formed.

First, in regions corresponding to the isolation regions MS, openings passing through a stack structure of the sacrificial insulating layers 118 and the interlayer insulating layers 120 may be formed, and the first horizontal conductive layer 102 and the first gate electrodes 130 may be formed.

Specifically, a mask layer may be formed on the first channel structures CH1, and openings may be formed therein using the mask. The openings may be formed to pass through the stack structure of the sacrificial insulating layers 118 and the interlayer insulating layers 120, to pass through the second horizontal conductive layer 104, and to extend in an X-direction. Subsequently, sacrificial spacer layers may be formed in the openings, and accordingly the second horizontal sacrificial layer may be exposed by an etch-back process. The exposed second horizontal sacrificial layer may be selectively removed, and then the upper and lower first and third horizontal sacrificial layers may be removed. The horizontal sacrificial layers may be removed by, for example, a wet etching process. During the process of removing the horizontal sacrificial layers, a portion of the first dielectric layer 142 exposed in a region from which the horizontal sacrificial layers are removed may also be removed. The first horizontal conductive layer 102 may be formed by depositing a conductive material in the region from which the horizontal sacrificial layers are removed, and then the sacrificial spacer layers may be removed in the openings. Subsequently, tunnel portions may be formed by removing the sacrificial insulating layers 118 exposed by the openings, and first gate electrodes 130 may be formed by filling the tunnel portions with a conductive material. The tunnel portions may be formed, for example, through a wet etching process of selectively removing the sacrificial insulating layers 118 with respect to the interlayer insulating layers 120. The conductive material included in the first gate electrodes 130 may include metal, polycrystalline silicon, or a metal silicide material. In the present operation, before the first gate electrodes 130 are formed, a dielectric layer having a conformal thickness may be deposited to form the gate dielectric layer 132 (see FIG. 2C). Subsequently, openings may be formed again by removing the conductive material.

In an example embodiment, when the conductive material is removed, portions of the first gate electrodes 130 may also be removed from the openings. When compared to the interlayer insulating layers 120, the first gate electrodes 130 may include regions partially recessed from the openings.

Subsequently, the isolation insulating layer 105 may be formed in the isolation regions MS.

The isolation insulating layer 105 may be formed by filling the openings with an insulating material and performing a planarization process to remove the mask layer and the insulating material. The insulating material may include silicon oxide, silicon nitride, or silicon oxynitride. In some example embodiments, first openings OP1 may be filled with a conductive material together with the insulating material.

The planarization process may be performed such that upper surfaces of the isolation insulating layer 105 in the isolation regions MS are positioned on a level the same as or substantially similar to upper surfaces of the first channel structures CH1.

Referring to FIG. 12I, the second gate electrode 150, and the upper isolation insulating layer 103 in the upper isolation regions SS may be formed.

The first upper insulating layer 192, the second gate electrode 150, and a second upper insulating layer 193 may be sequentially formed on the isolation regions MS, the first channel structures CH1, and the cell region insulating layer 190 through a deposition process.

The first upper insulating layer 192 may include a material different from that of the cell region insulating layer 190. For example, the first upper insulating layer 192 may include silicon nitride. The first upper insulating layer 192 may be a plate layer having a conformal thickness extending in an X-direction and a Y-direction. The second gate electrode 150 may be formed by depositing a conductive material, for example, doped polycrystalline silicon. The second gate electrode 150 may be formed to have a thickness greater than that of each of the first gate electrodes 130.

Trenches passing through the second gate electrode 150 to expose the first upper insulating layer 192, may be formed to form regions corresponding to the upper isolation regions SS. An insulating material may be deposited in the trenches and a planarization process may be performed thereon to form the upper isolation insulating layer 103.

Subsequently, referring to FIGS. 2A and 2C together, the second channel structures CH2, the third upper insulating layer 194, the fourth upper insulating layer 195 passing through the third upper insulating layer 194 to form a stud 181 in contact with the second channel pad 175 and covering the third upper insulating layer 194, the contact plugs 182 passing through the fourth upper insulating layer 194 to be in contact with the stud 181, and the upper interconnection 183 on the contact plugs 182 may be formed to form the semiconductor device 100 of FIGS. 1 to 2C.

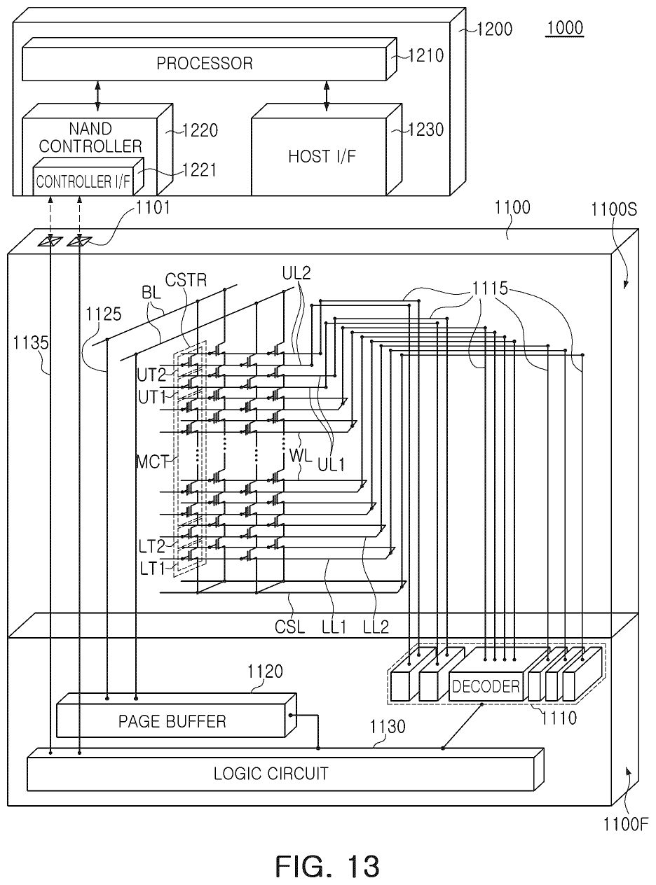

FIG. 13 is a schematic diagram illustrating a data storage system including a semiconductor device according to an example embodiment.

Referring to FIG. 13, a data storage system 1000 may include a semiconductor device 1100 and a controller 1200 electrically connected to the semiconductor device 1100. The data storage system 1000 may be a storage device including one or a plurality of semiconductor devices 1100 or an electronic device including the storage device. For example, the data storage system 1000 may be a solid state drive device (SSD) including one or a plurality of semiconductor devices 1100, a universal serial bus (USB), a computing system, a medical device, or a communication device.

The semiconductor device 1100 may be a non-volatile memory device, and may be, for example, the NAND flash memory device described above with reference to FIGS. 1 to 11. The semiconductor device 1100 may include a first semiconductor structure 1100F and a second semiconductor structure 1100S on the first semiconductor structure 1100 F. In some example embodiments, the first semiconductor structure 1100F may be disposed next to the second semiconductor structure 1100S. The first semiconductor structure 1100F may be a peripheral circuit structure including a decoder circuit 1110, a page buffer 1120, and a logic circuit 1130. The second semiconductor structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second semiconductor structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. In some example embodiments, the number of lower transistors LT1 and LT2 and the number of upper transistors UT1 and UT2 may be modified in various manners.

In some example embodiments, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In some example embodiments, the lower transistors LT1 and LT2 may include a lower erase control transistor LT1 and a ground selection transistor LT2 connected in series. In the present example embodiment, the gate lower lines LL2 of the ground selection transistor LT2 may refer to the lower gate electrode 130G of FIG. 2. The upper transistors UT1 and UT2 may include a string selection transistor UT1 and an upper erase control transistor UT2 connected in series. At least one of the lower erase control transistor LT1 and the upper erase control transistor UT2 may be used for an erase operation of erasing data stored in the memory cell transistors MCT using a GIDL phenomenon. In the present example embodiment, the gate upper line UL1 of the string selection transistor UT1 may refer to the second gate electrode 150 of FIG. 2.

The common source line CSL, the first and second gate lower lines LL1 and LL2, the word lines WL, and the first and second gate upper lines UL1 and UL2 may be electrically connected to the decoder circuit 1110 through first connection interconnections 1115 extending from an interior of the first semiconductor structure 1100F to the second semiconductor structure 1100S. The bit lines BL may be electrically connected to the page buffer 1120 through second connection interconnections 1125 extending from the interior of the first semiconductor structure 1100F to the second semiconductor structure 1100S.

In the first semiconductor structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through an input/output pad 1101 electrically connected to the logic circuit 1130. The input/output pad 1101 may be electrically connected to the logic circuit 1130 through an input/output connection interconnection 1135 extending from the interior of the first semiconductor structure 1100F to the second semiconductor structure 1100S.

The controller 1200 may include a processor 1210, a NAND controller 1220, and a host interface 1230. In some example embodiments, the data storage system 1000 may include a plurality of semiconductor devices 1100. In this case, the controller 1200 may control the plurality of semiconductor devices 1100.

The processor 1210 may control an overall operation of the data storage system 1000 including the controller 1200. The processor 1210 may operate according to desired (or alternatively, predetermined) firmware, and may access the semiconductor device 1100 by controlling the NAND controller 1220. The NAND controller 1220 may include a NAND interface 1221 processing communication with the semiconductor device 1100. A control instruction for controlling the semiconductor device 1100, data to be written to the memory cell transistors MCT of the semiconductor device 1100, and data to be read from the memory cell transistors MCT of the semiconductor device 1100 may be transmitted through the NAND interface 1221. The host interface 1230 may provide a communication function between the data storage system 1000 and an external host. When a control instruction is received from the external host through the host interface 1230, the processor 1210 may control the semiconductor device 1100 in response to the control instruction.

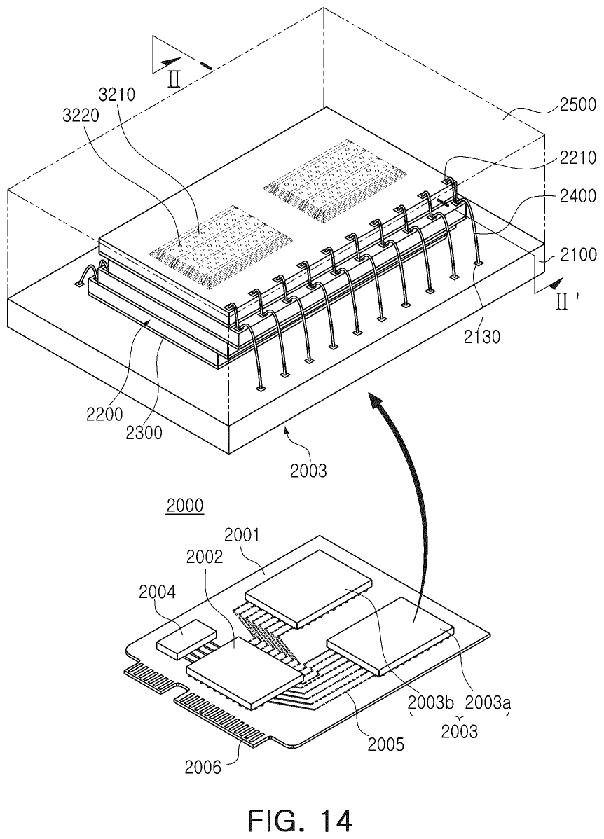

FIG. 14 is a schematic perspective view of a data storage system including a semiconductor device according to an example embodiment.

Referring to FIG. 14, a data storage system 2000 according to an example embodiment of the present disclosure may include a main substrate 2001, a controller 2002 mounted on the main substrate 2001, one or more semiconductor packages 2003, and a DRAM 2004. The semiconductor packages 2003 and the DRAM 2004 may be connected to the controller 2002 through interconnection patterns 2005 formed on the main substrate 2001.

The main board 2001 may include a connector 2006 including a plurality of pins coupled to an external host. The number and arrangement of the plurality of pins in the connector 2006 may vary depending on a communication interface between the data storage system 2000 and the external host. In some example embodiments, the data storage system 2000 may communicate with the external host according to one of interfaces such as universal flash storage (UFS), peripheral component interconnect express (PCI-Express), serial advanced technology attachment (SATA), M-Phy for universal serial bus (USB), and the like. In example embodiments, the data storage system 2000 may be operated by power supplied from the external host through the connector 2006. The data storage system 2000 may further include a power management integrated circuit (PMIC) distributing, to the controller 2002 and a semiconductor package 2003, power supplied from the external host.

The controller 2002 may write data to the semiconductor package 2003 or read data from the semiconductor package 2003, and may improve operating speed of the data storage system 2000.

The DRAM 2004 may be a buffer memory for alleviating a speed difference between the semiconductor package 2003, a data storage space, and the external host. The DRAM 2004, included in the data storage system 2000, may also operate as a type of cache memory, and may provide a space for temporarily storing data in a control operation on the semiconductor package 2003. When the DRAM 2004 is included in the data storage system 2000, the controller 2002 may further include a DRAM controller for controlling the DRAM 2004 in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, semiconductor chips 2200 on the package substrate 2100, adhesive layers 2300 disposed on lower surfaces of the semiconductor chips 2200, a connection structure 2400 electrically connecting the semiconductor chips 2200 and the package substrate 2100 to each other, and a molding layer 2500 covering the semiconductor chips 2200 and the connection structure 2400 on the package substrate 2100.

The package substrate 2100 may be a printed circuit board including package upper pads 2130. Each semiconductor chip 2200 may include an input/output pad 2210. The input/output pad 2210 may correspond to the input/output pad 1101 of FIG. 13. Each of the semiconductor chips 2200 may include gate stack structures 3210 and channel structures 3220. Each of the semiconductor chips 2200 may include the semiconductor device described above with reference to FIGS. 1 to 11.

In some example embodiments, the connection structure 2400 may be a bonding wire electrically connecting the input/output pad 2210 and the package upper pads 2130 to each other. Accordingly, in each of the first and second semiconductor packages 2003a and 2003b, the semiconductor chips 2200 may be electrically connected to each other using a bonding wire method, and may be electrically connected to the package upper pads 2130 of the package substrate 2100. In some example embodiments, in each of the first and second semiconductor packages 2003a and 2003b, the semiconductor chips 2200 may be electrically connected to each other by a connection structure including a through-silicon through (TSV) instead of the connection structure 2400 using the bonding wire method.

In some example embodiments, the controller 2002 and the semiconductor chips 2200 may be included in one package. In an example embodiment, the controller 2002 and the semiconductor chips 2200 may be mounted on an interposer substrate, different from the main substrate 2001, and the controller 2002 and the semiconductor chips may be connected to each other by an interconnection formed on the interposer substrate 2200.

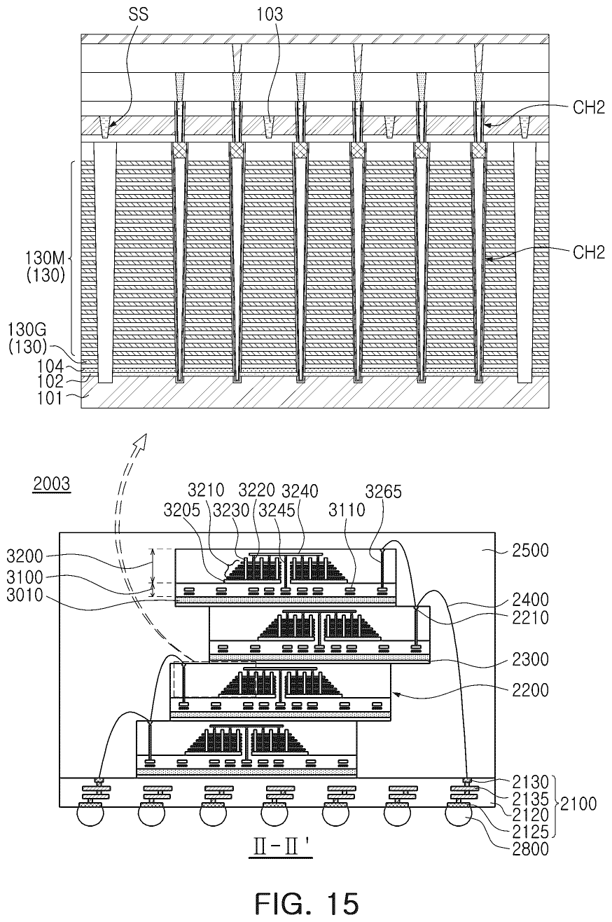

FIG. 15 is a schematic cross-sectional view of a semiconductor package according to an example embodiment. FIG. 15 illustrates an example embodiment of the semiconductor package 2003 of FIG. 14, and schematically illustrates a region obtained by cutting the semiconductor package 2003 of FIG. 14 along line II-II′.

Referring to FIG. 15, in the semiconductor package 2003, the package substrate 2100 may be a printed circuit board. The package substrate 2100 may include a package substrate body portion 2120, the package upper pads 2130 (see FIG. 14) disposed on the upper surface of the package substrate body 2120, lower pads 2125 disposed on a lower surface of the package substrate body portion 2120 and exposed through the lower surface, and internal interconnections 2135 electrically connecting the upper pads 2130 and the lower pads 2125 to each other in the package substrate body portion 2120. The upper pads 2130 may be electrically connected to the connection structures 2400. The lower pads 2125 may be connected to the interconnection patterns 2005 of the main substrate 2001 of the data storage system 2000 through conductive connection portions 2800, as illustrated in FIG. 14.

Each of the semiconductor chips 2200 may include a semiconductor substrate 3010 and a first semiconductor structure 3100 and a second semiconductor structure 3200 sequentially stacked on the semiconductor substrate 3010. The first semiconductor structure 3100 may include a peripheral circuit region including peripheral interconnections 3110. The second semiconductor structure 3200 may include a common source line 3205, a gate stack structure 3210 on the common source line 3205, channel structures 3220 and isolation regions 3230 passing through the gate stack structure 3210, bit lines 3240 electrically connected to the memory channel structures 3220, and cell contact plugs 3235 electrically connected to the word lines WL (see FIG. 13) of the gate stack structure 3210. As described above with reference to FIGS. 1 to 11, in each of the semiconductor chips 2200, the first channel structures CH1 may include the auxiliary channel layer 141 on the first channel layer 140, and a width of the first channel pad 145 may be greater than a width between external side surfaces of the first channel layer 140. In addition, a lower surface of the first channel pad 145 may be positioned on a level higher than that of an upper surface of the first channel layer 140.

Each of the semiconductor chips 2200 may include a through-interconnection 3245 electrically connected to the peripheral interconnections 3110 of the first semiconductor structure 3100 and extending into the second semiconductor structure 3200. The through-interconnection 3245 may be disposed on the outside of the gate stack structure 3210, and may further be disposed to pass through the gate stack structure 3210. Each of the semiconductor chips 2200 may further include the input/output pad 2210 (see FIG. 14) electrically connected to the peripheral interconnections 3110 of the first semiconductor structure 3100.

A contact area with second channel structures may be secured by forming a first channel pad having a width wider than a width between external side surfaces of a first channel layer, and providing the first channel pad to be spaced apart from the first channel layer, thereby providing a semiconductor device having an improved degree of integration and improved reliability, and a data storage system including the semiconductor device.

Any functional blocks shown in the figures and described above may be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The various and beneficial advantages and effects of the present disclosure are not limited to the above, and could be more easily understood based on the disclosed specific example embodiments.

While some example embodiments have been shown and described above, it will be apparent to those skilled in the art that modifications and variations could be made without departing from the scope of the present disclosure as defined by the appended claims.

What is claimed is:

1. A semiconductor device comprising:
first gate electrodes stacked on a substrate, the first gate electrodes spaced apart from each other;
a first channel structure passing through the first gate electrodes, the first channel structure including a first channel layer, a first dielectric layer between the first channel layer and the first gate electrodes, a first buried insulating layer filling an interior of the first channel layer, an auxiliary channel layer covering at least a portion of the first channel layer and the first dielectric layer, and a first channel pad on the first buried insulating layer; and
isolation regions passing through the first gate electrodes, the isolation regions spaced apart from each other,
wherein the auxiliary channel layer is in contact with the first channel pad, and
the first channel pad is spaced apart from the first dielectric layer by the auxiliary channel layer.

2. The semiconductor device of claim 1, wherein a width of the first channel pad is wider than a width between external side surfaces of the first channel layer.

3. The semiconductor device of claim 1, wherein the first channel pad is electrically connected to the auxiliary channel layer and the first channel layer.

4. The semiconductor device of claim 1, wherein
the first channel structure further includes a void in the first buried insulating layer, and
the void is spaced apart from the first channel pad.

5. The semiconductor device of claim 1, wherein the auxiliary channel layer conformally covers an upper surface of the first dielectric layer and an upper surface of the first channel layer.

6. The semiconductor device of claim 1, wherein a thickness of the auxiliary channel layer is different from a thickness of the first channel layer.

7. The semiconductor device of claim 1, wherein an upper surface of the first dielectric layer is on a level same as an upper surface of the first channel layer.

8. The semiconductor device of claim 1, wherein the auxiliary channel layer is along an external side surface of the first buried insulating layer, an external side surface of the first channel pad, and an internal side surface of the first channel layer.

9. The semiconductor device of claim 1, wherein the first dielectric layer includes a ferroelectric layer.

10. The semiconductor device of claim 1, wherein
the first buried insulating layer includes a first region at a same level as the first channel layer, and a second region at a higher level than the first channel layer, and
a first width of the first region is less than a second width of the second region.

11. The semiconductor device of claim 1, further comprising:
a first insulating layer on the first channel structure and the isolation regions:
a second gate electrode on the first insulating layer; and
a second channel structure passing through the second gate electrode, the second channel structure including a second channel layer, a second dielectric layer between the second channel layer and the second gate electrode, a second buried insulating layer filling an interior of the second channel layer, and a second channel pad on the second buried insulating layer.

12. The semiconductor device of claim 11, wherein a central axis of the first channel structure and a central axis of the second channel structure are offset from each other.

13. A semiconductor device comprising:
first gate electrodes stacked on a substrate and apart from each other;
a first channel structure passing through the first gate electrodes, the first channel structure including a first channel layer, a first dielectric layer between the first channel layer and the first gate electrodes, a first buried insulating layer filling an interior of the first channel layer, an auxiliary channel layer covering at least a portion of the first channel layer and the first dielectric layer, and a first channel pad on the first buried insulating layer; and
isolation regions passing through the first gate electrodes, the isolation regions spaced apart from each other;
wherein the auxiliary channel layer is in contact with the first channel pad, and
a lower surface of the first channel pad is positioned on a level higher than an upper surface of the first channel layer.

14. The semiconductor device of claim 13, wherein an upper surface of the auxiliary channel layer is on a same level as an upper surface of the first channel pad.

15. The semiconductor device of claim 13, wherein
the first dielectric layer includes a first layer and a second layer sequentially stacked from the first channel layer, and
a first length between an upper surface of the first channel pad and an upper surface of the second layer is less than or equal to a second length between the upper surface of the first channel pad and an upper surface of the first layer.

16. The semiconductor device of claim 15, wherein the second length is less than or equal to a third length between the upper surface of the first channel pad and the upper surface of the first channel layer.

17. The semiconductor device of claim 15, wherein the first dielectric layer further includes a third layer between side surfaces of the first gate electrodes and the second layer.

18. The semiconductor device of claim 17, wherein the third layer is coplanar with an upper surface of the auxiliary channel layer and the upper surface of the first channel pad.

19. A data storage system comprising:
a semiconductor storage device including a lower substrate, circuit elements on one side of the lower substrate, an upper substrate on the circuit elements, first gate electrodes stacked on the upper substrate and spaced apart from each other, a first channel structure passing through the first gate electrodes, and isolation regions passing through the first gate electrodes and spaced apart from each other, and an input/output pad electrically connected to the circuit elements; and
a controller electrically connected to the semiconductor storage device through the input/output pad, the controller controlling the semiconductor storage device,
wherein the first channel structure includes a first channel layer, a first dielectric layer between the first channel layer and the first gate electrodes, a first buried insulating layer filling an interior of the first channel layer, an auxiliary channel layer covering at least a portion of the first channel layer and the first dielectric layer, and a first channel pad on the first buried insulating layer,
the auxiliary channel layer is in contact with the first channel pad, and
a lower surface of the first channel pad is at a level higher than an upper surface of the first channel layer.

20. The data storage system of claim 19, wherein the auxiliary channel layer is along an external side surface of the first buried insulating layer, an external side surface of the first channel pad, and an internal side surface of the first channel layer.
